(19) United States
(12) Patent Application Publication
(10) Pub. No.: US 2025/0098427 A1
(43) Pub. Date: Mar. 20, 2025

(54) DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yu Wu, Beijing (CN); Changchang Liu, Beijing (CN); Fei Fang, Beijing (CN); Ling Shi, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/578,895

(22) PCT Filed: Mar. 31, 2023
(86) PCT No.: PCT/CN2023/085588

§ 371 Date: Jan. 12, 2024

(30) Foreign Application Priority Data
Nov. 30, 2022 (CN) 202211534232.6
Jan. 18, 2023 (WO) PCT/CN2023/072832

(51) Int. Cl. H10K 59/122; H10K 39/34; H10K 59/80

(52) U.S. Cl. CPC H10K 59/122; H10K 39/34; H10K 59/8792

(57) ABSTRACT

A display substrate and a display device are disclosed. The display substrate includes a base substrate and sub-pixels arranged on the base substrate, the sub-pixel includes a sub-pixel driving circuit and a light-emitting element including an anode pattern coupled to the sub-pixel driving circuit. The display substrate further includes pixel definition patterns, at least one of which includes at least one pixel aperture, at least a portion of the light-emitting element is located in the pixel aperture, an orthographic projection of the at least one pixel definition pattern onto the base substrate covers at least a portion of an orthographic projection of the sub-pixel driving circuit onto the base substrate, and covers at least a portion of an orthographic projection of a gap between at least two adjacent sub-pixel driving circuits onto the base substrate, and the pixel definition patterns are configured to shield light.

### CROSS-REFERENCE TO RELATED APPLICATIONS

This application claims priority to Chinese Patent Application No. 202211534232.6 filed in China on Nov. 30, 2022, which is hereby incorporated by reference in its entirety. This application claims priority to PCT International Application No. PCT/CN2023/072832 filed on Jan. 18, 2023, which is hereby incorporated by reference in its entirety.

### TECHNICAL FIELD

The present disclosure relates to the technical field of displaying, and in particular, to a display substrate and a display device.

### BACKGROUND

Full screen displaying is developing rapidly in recent years, and new requirements for the screen shape have been raised. For the under display camera (UDC) technology, a front camera is hidden under the display screen, and an area provided with the camera is capable of normally display an image, so as to realize full-screen displaying in a real sense. The under display camera technology address a contradiction between the displaying integrity and the front camera, such that the display integrity and the display screen-to-body ratio can be improved.

### SUMMARY

The present disclosure to provide a display substrate and a display device.

In order to achieve this, the present disclosure provides the following technical solutions.

In a first aspect of the present disclosure, a display substrate is provided, including: a base substrate and a plurality of sub-pixels arranged on the base substrate, where the sub-pixel includes a sub-pixel driving circuit and a light-emitting element, the light-emitting element includes an anode pattern, and the anode pattern is coupled to the sub-pixel driving circuit; and the display substrate further includes:
a plurality of pixel definition patterns, where at least one pixel definition pattern in the plurality of pixel definition patterns includes at least one pixel aperture, at least a portion of the light-emitting element is located in the pixel aperture, an orthographic projection of the at least one pixel definition pattern onto the base substrate covers at least a portion of an orthographic projection of the sub-pixel driving circuit onto the base substrate, and covers at least a portion of an orthographic projection of a gap between at least two adjacent sub-pixel driving circuits onto the base substrate, and the plurality of pixel definition patterns are configured to shield light.

Optionally, the plurality of pixel definition patterns are independent of one another.

Optionally, at least some pixel definition patterns in the plurality of pixel definition patterns are formed as a one-piece structure.

Optionally, the at least one pixel definition pattern includes a black pixel definition pattern.

Optionally, the sub-pixel driving circuit includes a first driving portion and/or a second driving portion, where an orthographic projection of the first driving portion onto the base substrate does not overlap with an orthographic projection of a corresponding pixel aperture onto the base substrate, and an orthographic projection of the second driving portion onto the base substrate overlaps with an orthographic projection of the corresponding pixel aperture onto the base substrate;
the orthographic projection of the at least one pixel definition pattern onto the base substrate fully covers the orthographic projection of the first driving portion onto the base substrate.

Optionally, a minimum spacing between adjacent sub-pixel driving circuits along a first direction is greater than or equal to a width of one sub-pixel driving circuit in the first direction; a minimum spacing between adjacent sub-pixel driving circuits in a second direction is greater than or equal to one half of a width of one sub-pixel in the second direction; the first direction intersects with the second direction;

The adjacent sub-pixel driving circuits in the first direction are electrically connected via a first signal line; and/or adjacent sub-pixel driving circuits in the second direction are electrically connected via a second signal line.

Optionally, the plurality of sub-pixels are divided into a plurality of sub-pixel groups distributed in an array, and each sub-pixel group includes at least two sub-pixels; the plurality of sub-pixel groups are distributed as islands, and a minimum distance between two closest sub-pixel driving circuits in adjacent sub-pixel groups in a first direction is greater than or equal to a width of one sub-pixel driving circuit in the first direction; a minimum distance between two closest sub-pixel driving circuits in adjacent sub-pixel groups in the second direction is greater than or equal to one half of a width of one sub-pixel in the second direction; the first direction intersects with the second direction;
the two closest sub-pixel driving circuits in the adjacent sub-pixel groups in the first direction are electrically connected via a first signal line; and/or the two closest sub-pixel driving circuits in the adjacent sub-pixel groups in the second direction are electrically connected via a second signal line.

Optionally, the first signal line is a transparent signal line and includes at least one of an initialization signal line, a gate line, a reset signal line and a light-emitting control signal line;
the second signal line is a transparent signal line and includes a data line and/or a power supply line.

Optionally, in the at least some pixel definition patterns formed as the one-piece structure, a spacing region is arranged between adjacent pixel definition patterns, an orthographic projection of a boundary of the spacing region onto the base substrate surrounds at least a portion of the first signal line and/or at least a portion of the second signal line in the display substrate.

Optionally, an orthographic projection of an outer boundary of the pixel definition pattern onto the base substrate is rectangular.

Optionally, an orthographic projection of an outer boundary of the pixel definition pattern onto the base substrate is circular.

Optionally, the pixel definition pattern includes a pixel definition main body portion and at least one pixel definition protruding portion, the at least one pixel definition protruding portion is coupled to the pixel definition main body portion, an overlapping area between an orthographic projection of the pixel definition main body portion onto the base substrate and an orthographic projection of a corresponding sub-pixel driving circuit onto the base substrate is greater than an overlapping area between an orthographic projection of the pixel definition protruding portion onto the base substrate and the orthographic projection of the corresponding sub-pixel driving circuit onto the base substrate.

Optionally, sub-pixel driving circuits included in the sub-pixel group are arranged along the first direction; and
pixel definition patterns corresponding to sub-pixel driving circuits in the same one sub-pixel group are formed as a one-piece structure, and the pixel definition patterns formed as the one-piece structure cover at least a portion of a region located between adjacent sub-pixel driving circuits.

Optionally, pixel definition patterns corresponding to sub-pixel driving circuits, which are in sub-pixel groups located in a same column in the second direction, are formed as a one-piece structure.

Optionally, the display substrate further includes an encapsulation layer and a plurality of black matrix patterns, the encapsulation layer is located between the plurality of black matrix patterns and the base substrate, an orthographic projection of the black matrix pattern onto the base substrate at least partially overlaps with an orthographic projection of a corresponding pixel definition pattern onto the base substrate.

Optionally, a contour of the orthographic projection of the black matrix pattern onto the base substrate is substantially the same as a contour of the orthographic projection of the corresponding pixel definition pattern onto the base substrate.

Optionally, an orthographic projection of an inner boundary of the black matrix pattern onto the base substrate surrounds an orthographic projection of an inner boundary of the corresponding pixel definition pattern onto the base substrate.

Optionally, an orthographic projection of an outer boundary of the pixel definition pattern onto the base substrate surrounds an orthographic projection of a corresponding black matrix pattern onto the base substrate.

Optionally, the display substrate includes a first display region and a second display region, where the first display region is located at least at one side of the second display region;
the plurality of sub-pixels includes a plurality of first sub-pixels and a plurality of second sub-pixels, the plurality of first sub-pixels are located in the first display region, the plurality of second sub-pixels are located in the second display region, a pixel density for the plurality of second sub-pixels is less than or equal to a pixel density for the plurality of first sub-pixels, the plurality of pixel definition patterns are located in the second display region.

Optionally, a light transmittance of the first display region is less than a light transmittance of the second display region.

In a second aspect of the present disclosure, a display device is provided, the display device includes the above-mentioned display substrate. The display device further includes a photosensitive sensor, the photosensitive sensor is located at a non-displaying side of the display substrate and at least a portion of the photosensitive sensor is located in the second display region.

### BRIEF DESCRIPTION OF THE DRAWINGS

The drawings described herein are used to provide a further understanding of the disclosure and form a part of the disclosure. Schematic embodiments and descriptions of the disclosure are used to explain the disclosure and do not constitute undue limitation on the disclosure. In the drawings,

FIG. 1 is a schematic circuit configuration diagram of a sub-pixel driving circuit provided in an embodiment of the present disclosure;

FIG. 2 is a driving timing diagram of a sub-pixel driving circuit provided in an embodiment of the present disclosure;

FIG. 3 is an isolated-islands layout for sub-pixel driving circuits provided by an embodiment of the present disclosure;

FIG. 4 is an enlarged view of section A1 in FIG. 3;

FIG. 5 is a schematic diagram showing provision of an anode pattern on the basis of FIG. 3;

FIG. 6 is a schematic diagram of the anode pattern provided in FIG. 3;

FIG. 7 is a first schematic diagram showing provision of a pixel definition pattern on the basis of FIG. 5;

FIG. 8 is a schematic diagram of the pixel definition pattern provided in FIG. 7;

FIG. 9a is a schematic diagram showing provision of a black matrix on the basis of FIG. 7;

FIG. 9b is a modified structure of section A4 in FIG. 9a;

FIG. 9c is a modified structure of section A5 in FIG. 9a.

FIG. 10 is a schematic diagram of the black matrix provided in FIG. 9a;

FIG. 11 is an enlarged view of section A2 in FIG. 9a;

FIG. 12 is a second schematic diagram showing provision of a pixel definition pattern on the basis of FIG. 5;

FIG. 13 is a schematic diagram of the pixel definition pattern provided in FIG. 12;

FIG. 14 is a schematic diagram showing provision of a black matrix on the basis of FIG. 12;

FIG. 15 is a schematic diagram of the black matrix provided in FIG. 14;

FIG. 16 is an enlarged view of section A3 in FIG. 14;

FIG. 17 is a clustering layout for sub-pixel driving circuits provided by an embodiment of the present disclosure;

FIG. 18 is a schematic diagram showing provision of an anode pattern on the basis of FIG. 17;

FIG. 19 is a schematic diagram of the anode pattern provided in FIG. 18;

FIG. 20 is a schematic diagram showing provision of a pixel definition pattern on the basis of FIG. 18;

FIG. 21 is a layout diagram of the pixel definition pattern provided in FIG. 20;

FIG. 22 is a schematic diagram showing provision of a black matrix on the basis of FIG. 20;

FIG. 23 is a schematic diagram of the black matrix provided in FIG. 22;

FIG. 24 is a layout diagram of a sub-pixel driving circuit provided in an embodiment of the present disclosure;

FIG. 25 is a schematic diagram showing a first overlapping between a sub-pixel driving circuit and a pixel definition pattern provided by an embodiment of the present disclosure;

FIG. 26 is a schematic diagram showing signal line connections between sub-pixel driving circuits having the clustering layout according to an embodiment of the present disclosure;

FIG. 27 is a schematic diagram showing a second overlapping between a sub-pixel driving circuit and a pixel definition pattern provided by an embodiment of the present disclosure;

FIG. 28 is a schematic diagram showing a structure of a display substrate according to an embodiment of the present disclosure;

FIG. 29 is a schematic diagram showing light emissions at a first display region and a second display region provided in an embodiment of the present disclosure;

FIG. 30 is a layout diagram of a pixel definition layer provided by an embodiment of the present disclosure;

FIG. 31 is a schematic diagram showing some film layers of a display substrate provided by an embodiment of the present disclosure; and

FIGS. 32 to 60 are schematic diagrams showing respective film layers of the sub-pixel driving circuit as shown in FIG. 24 and stack structures for some of the film layers.

### DETAILED DESCRIPTION

In order to further explain the display substrate and the display device provided by the embodiments of the present disclosure, a detailed description will be given below with reference to the accompanying drawings.

Currently, there are various challenges for the UDC technology, which mainly includes: firstly, the transmission rate of the display screen is relatively low, a large part of incident light from the outside is blocked, which may affect the shooting quality; and secondly, the reflectivity of the display screen is relatively high, the complex and periodic opaque patterns in the display screen may cause diffraction blur and flare on the camera sensor, which may affect the display effect.

In display products using UDC technology, the method of increasing the transmittance includes: reducing the number of via holes, as well as compressing the process limitations, such as hiding all metal layers except for an anode under the anode, etc. However, there is no effective solution to reduce the high reflectivity in the conventional display products using UDC technology. Therefore, there is a need for a new solution to reduce the high reflectivity in the display products using UDC technology.

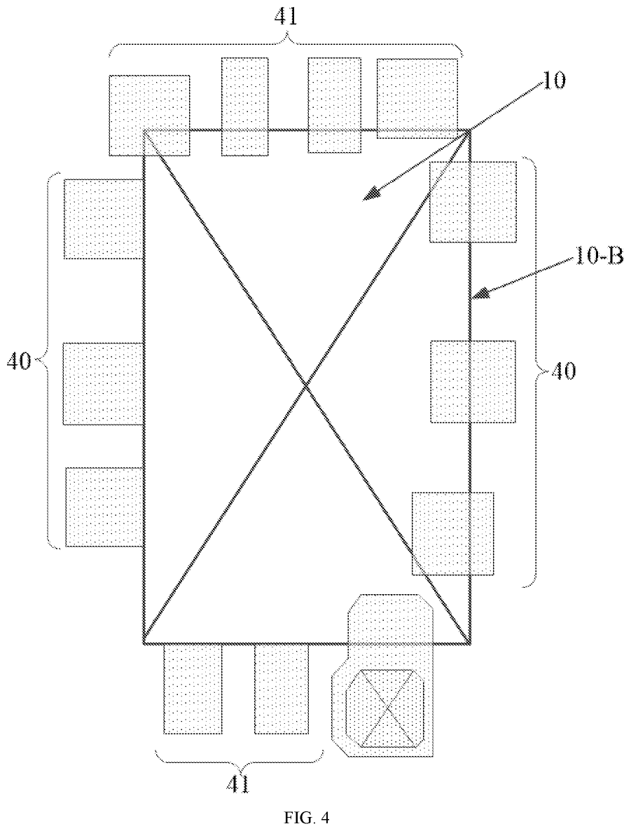

With reference to FIGS. 4, 11, 16 and 20, an embodiment of the present disclosure provides a display substrate. The display substrate includes a base substrate and a plurality of sub-pixels arranged on the base substrate. The sub-pixel includes a sub-pixel driving circuit 10 and a light-emitting element. The light-emitting element includes an anode pattern 20, and the anode pattern 20 is coupled to the sub-pixel driving circuit 10. The display substrate further includes: a plurality of pixel definition patterns PDL, at least one pixel definition pattern PDL of the plurality of pixel definition patterns PDL includes at least one pixel aperture 30, at least a portion of the light-emitting element is located in the pixel aperture 30. An orthographic projection of the at least one pixel definition pattern PDL onto the base substrate covers at least a portion of an orthographic projection of the sub-pixel driving circuit 10 onto the base substrate, and the orthographic projection of the at least one pixel definition pattern PDL onto the base substrate covers at least a portion of an orthographic projection of a gap between at least two adjacent sub-pixel driving circuits 10 onto the base substrate. The plurality of pixel definition patterns PDL are configured to shield light.

Illustratively, at least one of the pixel definition patterns PDL includes a black pixel definition pattern.

Illustratively, an orthographic projection of the pixel definition pattern PDL onto the base substrate at least partially overlaps with an orthographic projection of a boundary 10-B of a corresponding sub-pixel driving circuit 10 onto the base substrate.

Illustratively, each pixel definition pattern includes a pixel aperture.

Illustratively, the light-emitting element further includes a light-emitting functional layer, at least a portion of the light-emitting functional layer is located in the pixel aperture.

Illustratively, an orthographic projection of the anode pattern onto the base substrate overlaps with an orthographic projection of the pixel aperture onto the base substrate.

As shown in FIGS. 3 and 4, illustratively, the display substrate includes a plurality of sub-pixels. The plurality of sub-pixels includes a plurality of sub-pixel driving circuits 10 arranged in an array. The plurality of sub-pixel driving circuits 10 are divided into a plurality of rows of sub-pixel driving circuits 10 and a plurality of columns of sub-pixel driving circuits 10. The plurality of rows of sub-pixel driving circuits 10 are arranged along a second direction, and each row of sub-pixel driving circuits 10 includes multiple sub-pixel driving circuits 10 arranged along a first direction. The plurality of columns of sub-pixel driving circuits 10 are arranged along the first direction, and each column of sub-pixel driving circuits 10 includes multiple sub-pixel driving circuits 10 arranged along the second direction. Illustratively, the first direction and the second direction intersect with each other. For example, the first direction includes a transverse direction and the second direction includes a longitudinal direction.

Illustratively, the sub-pixel includes the sub-pixel driving circuit 10 and the light-emitting element. The sub-pixel driving circuit 10 is coupled to the anode pattern 20 of the light-emitting element, and is configured for supplying a driving signal to the light-emitting element to drive the light-emitting element to emit light.

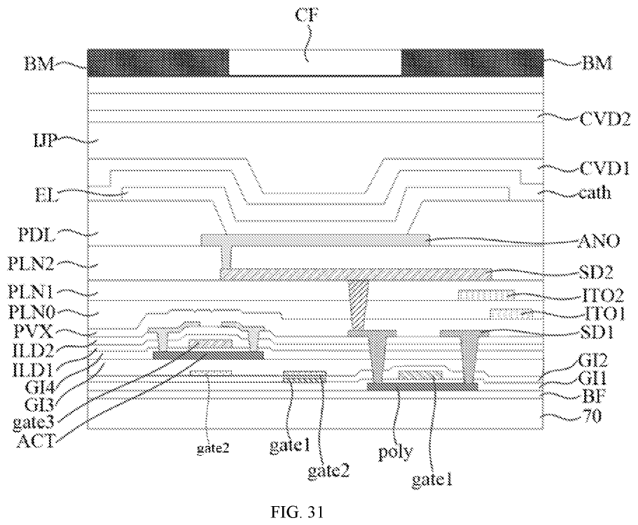

As shown in FIG. 31, exemplarily, the display substrate includes following elements stacked in sequence in a direction away from the base substrate 70: a buffer layer BF, a first active layer poly, a first gate electrode insulating layer GI1, a first gate metal layer gate1, a second gate electrode insulating layer GI2, a second gate metal layer gate2, a third gate electrode insulating layer GI3, a second active layer ACT, a fourth gate electrode insulating layer GI4, a third gate metal layer gate3, a first interlayer insulating layer ILD1, a second interlayer insulating layer ILD2, a first source and drain metal layer SD1 and a passivation layer PVX, a first ITO layer ITO1, a basic planarization layer PLN0, a second ITO layer ITO2, a first planarization layer PLN1, a second source and drain metal layer SD2, a second planarization layer PLN2, an anode layer ANO, a pixel definition layer (including a pixel definition pattern PDL), a light-emitting functional layer EL, a cathode layer cath, a first inorganic encapsulation layer CVD1, an organic encapsulation layer IJP, a second inorganic encapsulation layer CVD2, and a color film structure (including a black matrix pattern BM and a color film pattern CF).

Illustratively, the first active layer, the first gate electrode insulating layer, the first gate metal layer, the second gate electrode insulating layer, the second gate metal layer, the third gate electrode insulating layer, the second active layer, the third gate electrode insulating layer, the third gate metal layer, the interlayer insulating layer, the first source and drain metal layer, the passivation layer, the first transparent metal layer, the first planarization layer, the second transparent metal layer, the second planarization layer and the second source and drain metal layer are used for forming the sub-pixel driving circuit 10, and some signal lines included in the display substrate.

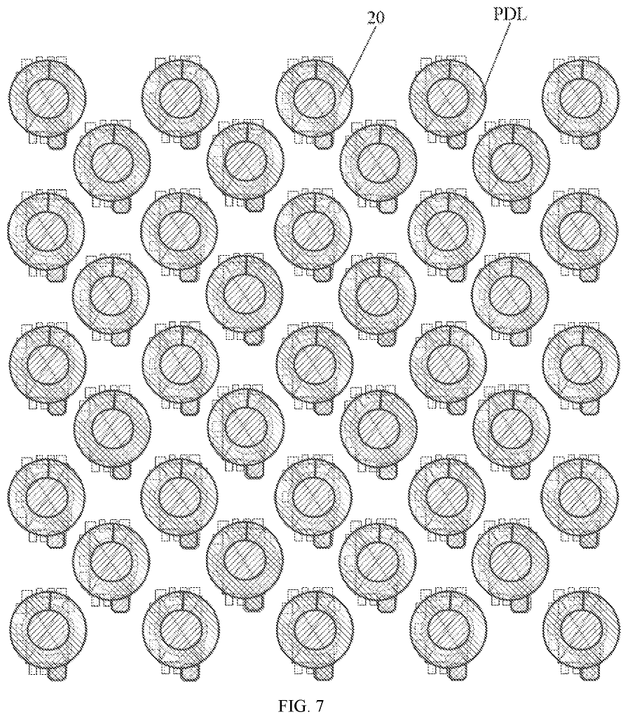

As shown in FIGS. 8, 11, 13 and 21, illustratively, the pixel definition layer includes the plurality of pixel definition patterns PDL, the pixel definition pattern PDL includes at least one pixel aperture 30. An orthographic projection of the pixel definition pattern PDL onto the base substrate at least partially overlaps with an orthographic projection of a boundary of a corresponding anode pattern 20 onto the base substrate. An orthographic projection of the pixel aperture 30 onto the base substrate is located inside the orthographic projection of the anode pattern 20 onto the base substrate.

According to the specific structure of the above-mentioned display substrate, it can be seen that the display substrate provided by the embodiments of the present disclosure includes the plurality of pixel definition patterns (PDL), where the pixel definition patterns (PDL) can shield light, the orthographic projection of the at least one pixel definition pattern (PDL) onto the base substrate covers at least a portion of the orthographic projection of the sub-pixel driving circuit 10 onto the base substrate, and covers at least a portion of the orthographic projection of the gap between at least two adjacent sub-pixel driving circuits 10 onto the base substrate. This arrangement enables the pixel definition pattern PDL to form the pixel aperture 30 on the anode pattern 20, thereby ensuring normal displaying of the sub-pixel. This arrangement also enables the pixel definition pattern PDL to shield at least a portion of the corresponding sub-pixel driving circuit 10 and to shield at least a portion of the gap between the at least two adjacent sub-pixel driving circuits, which can reduce a reflective rate of ambient light reflected by the non-transparent metal film layer in the sub-pixel driving circuit 10, thereby effectively improving the user experience.

Additionally, the pixel definition pattern PDL is arranged to include a black pixel definition pattern PDL, so that the pixel definition pattern PDL can absorb ambient light, thereby further reducing the reflection of the ambient light by the display substrate, and further improving the user experience.

Referring to FIGS. 4, 11, 16 and 20, in some embodiments, the orthographic projection of the pixel definition pattern PDL onto the base substrate, fully covers the orthographic projection of the boundary 10-B of the corresponding sub-pixel driving circuit 10 onto the base substrate.

This arrangement further increases the area of the corresponding sub-pixel driving circuit 10 shielded by the pixel definition pattern PDL, which can further reduce the reflective rate of the ambient light reflected by the non-transparent metal film layer in the sub-pixel driving circuit 10, thereby effectively improving the user experience.

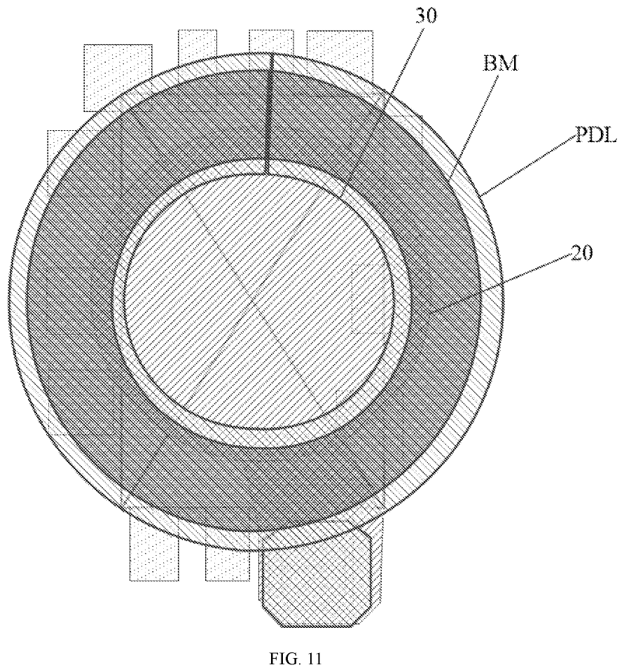

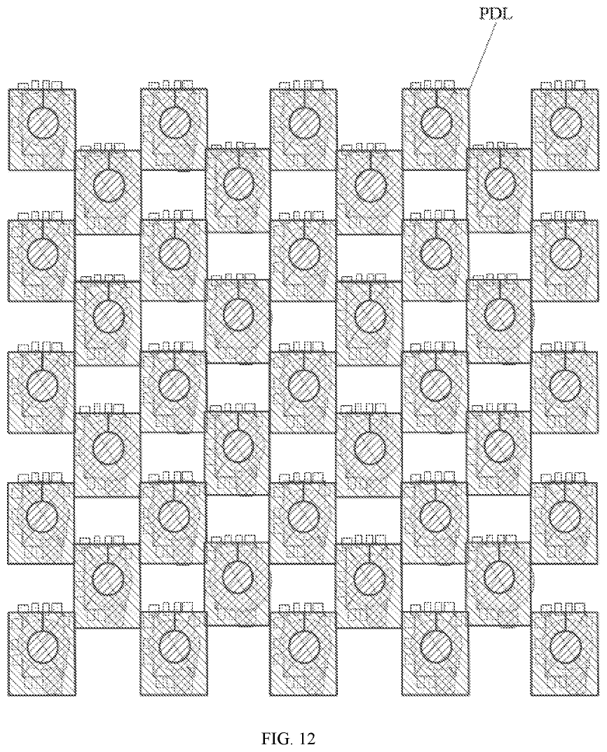

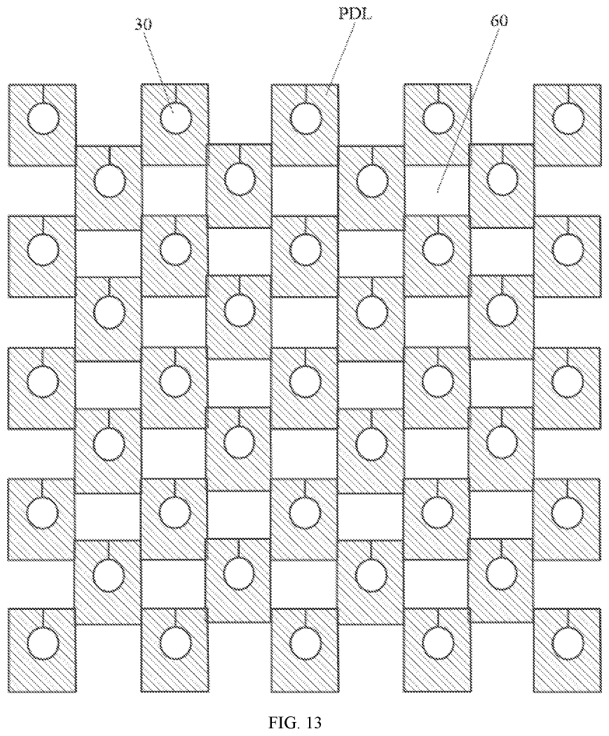

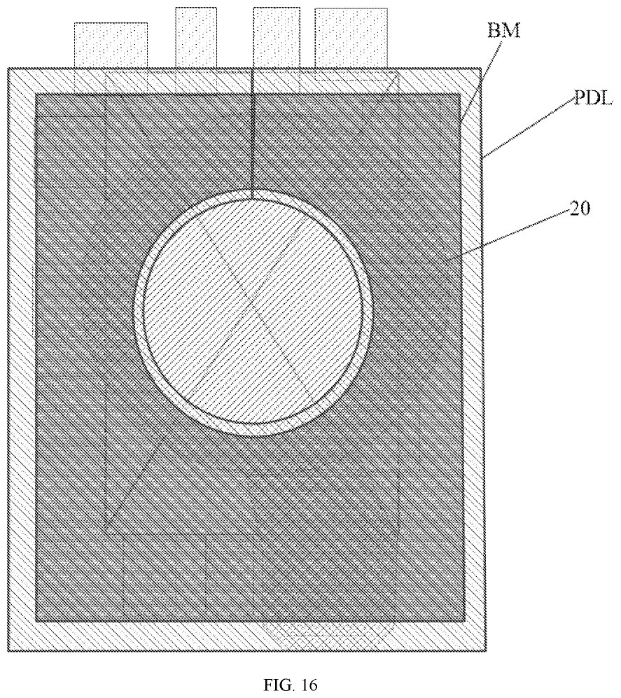

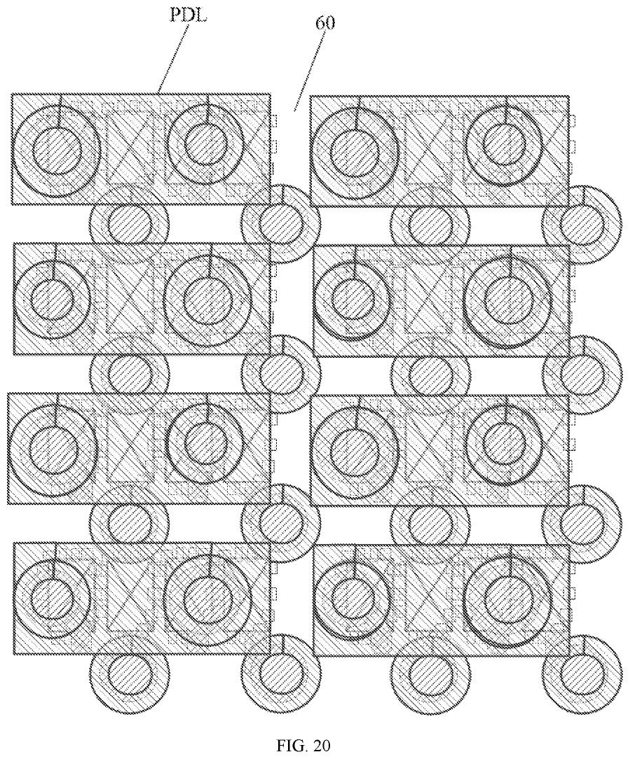

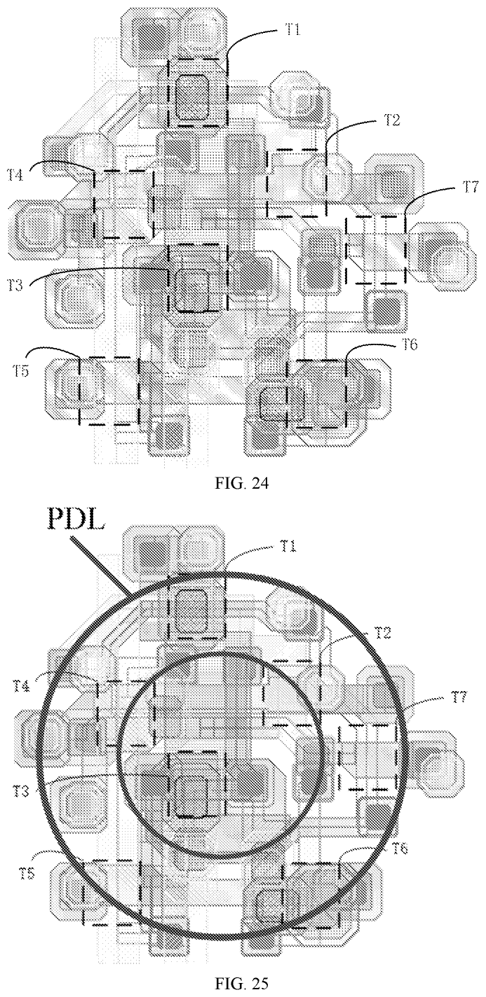

As shown in FIG. 7, FIG. 8, FIG. 11, FIG. 12, FIG. 13, FIG. 16, FIG. 20, FIG. 21, FIG. 24, and FIG. 25, in some embodiments, the sub-pixel driving circuit 10 includes a first driving portion and/or a second driving portion. An orthographic projection of the first driving portion onto the base substrate does not overlap with an orthographic projection of a corresponding pixel aperture 30 onto the base substrate. An orthographic projection of the second driving portion onto the base substrate overlaps with the orthographic projection of the corresponding pixel aperture 30 onto the base substrate. The orthographic projection of the at least one pixel definition pattern PDL onto the base substrate fully covers the orthographic projection of the first driving portion onto the base substrate.

As shown in FIGS. 24 and 25, an annular pixel definition pattern PDL is taken as an example. A layout structure of seven transistors included in the sub-pixel driving circuit 10 is illustrated in FIG. 24. An overlapping relationship between the sub-pixel driving circuit 10 and the pixel definition pattern PDL is illustrated in FIG. 25. In FIG. 25, a portion of the sub-pixel driving circuit 10 which overlaps with the pixel definition pattern PDL is the second driving portion, and a portion of the sub-pixel driving circuit 10 which does not overlap with the pixel definition pattern PDL is the first driving portion.

Illustratively, the sub-pixel driving circuit 10 may include only the first driving portion, namely, an orthographic projection of an entirety of the sub-pixel driving circuit 10 onto the base substrate does not overlap with the orthographic projection of the corresponding pixel aperture 30 onto the base substrate.

In the display substrate provided in the above-mentioned embodiment, by arranging the orthographic projection of the pixel definition pattern PDL onto the base substrate to fully cover the orthographic projection of the first driving portion onto the base substrate, the area of the sub-pixel driving circuit 10 shielded by the corresponding pixel definition pattern PDL can be further increased, which can further reduce the reflective rate of the ambient light reflected by the non-transparent metal film layer in the sub-pixel driving circuit 10, thereby effectively improving the user experience.

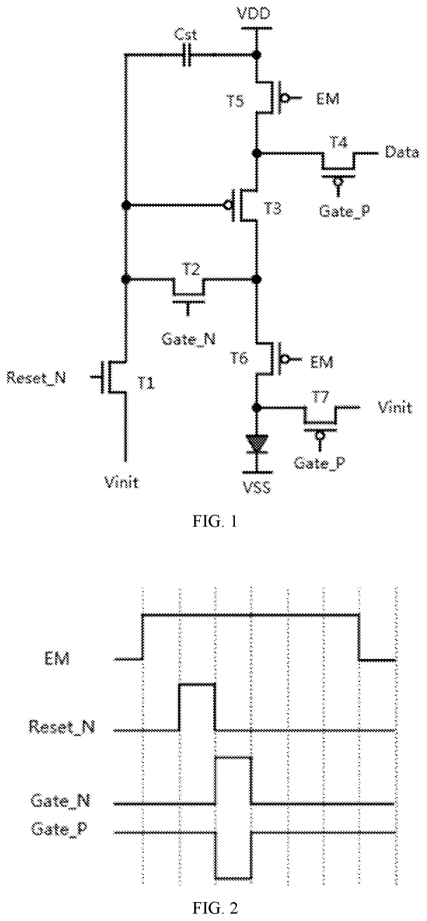

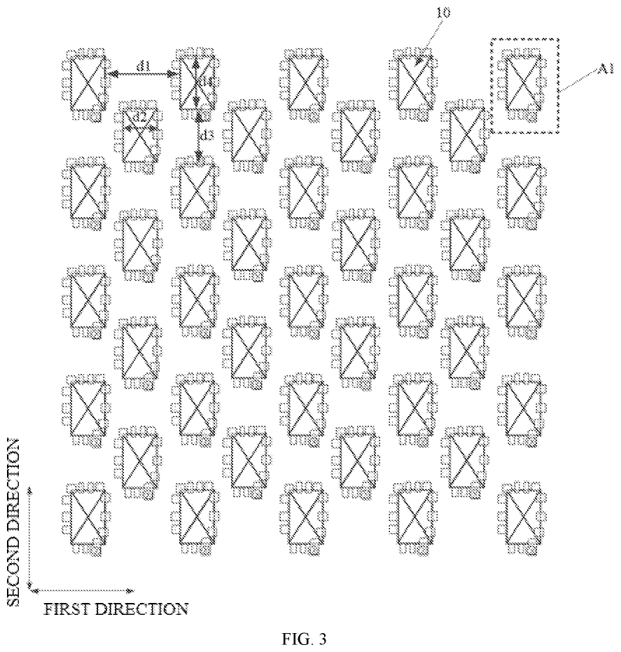

As shown in FIGS. 1 and 2, in some embodiments, the sub-pixel driving circuit 10 adopts a 7T1C structure, i.e., 7 transistors and 1 storage capacitor, but the disclosure is not limited thereto.

The sub-pixel driving circuit 10 includes a first transistor T1, a second transistor T2, a third transistor T3, a fourth transistor T4, a fifth transistor T5, a sixth transistor T6, a seventh transistor T7 and a storage capacitor Cst. The first transistor T1 and the second transistor T2 are NMOS transistors, the third transistor T3, the fourth transistor T4, the fifth transistor T5, the sixth transistor T6, and the seventh transistor T7 are PMOS transistors.

The display substrate further includes: a power supply line VDD, a light-emitting control signal line EM, a data line Data, a first scanning line Gate_P, a second scanning line Gate_N, a reset signal line Reset_N, and an initialization signal line Vinit.

A gate electrode of the first transistor T1 is coupled to a corresponding reset signal line Reset_N, a first electrode of the first transistor T1 is coupled to the initialization signal line Vinit, and a second electrode of the first transistor T1 is coupled to a gate electrode of the third transistor T3.

Agate electrode of the second transistor T2 is coupled to a corresponding second scanning line Gate_N, a first electrode of the second transistor T2 is coupled to a second electrode of the third transistor T3, and a second electrode of the second transistor T2 is coupled to the gate electrode of the third transistor T3.

Agate electrode of the fourth transistor T4 is coupled to a corresponding first scanning line Gate_P, a first electrode of the fourth transistor T4 is coupled to a corresponding data line Data, and a second electrode of the fourth transistor T4 is coupled to a first electrode of the third transistor T3.

A gate electrode of the fifth transistor T5 is coupled to a corresponding light-emitting control signal line EM, a first electrode of the fifth transistor T5 is coupled to the power supply line VDD, and a second electrode of the fifth transistor T5 is coupled to the first electrode of the third transistor T3.

A gate electrode of the sixth transistor T6 is coupled to a corresponding light-emitting control signal line EM, a first electrode of the sixth transistor T6 is coupled to the second electrode of the third transistor T3, a second electrode of the sixth transistor T6 is coupled to an anode pattern 20 of a corresponding light-emitting element, and a cathode connected to the light-emitting element receives a power supply signal VSS.

A gate electrode of the seventh transistor T7 is coupled to a corresponding first scanning line Gate_P, a first electrode of the seventh transistor T7 is coupled to the initialization signal line Vinit, and a second electrode of the seventh transistor T7 is coupled to the anode pattern 20 of the corresponding light-emitting element.

Illustratively, an operating process of the sub-pixel driving circuit 10 includes the following stages.

In a first stage, the light-emitting control signal line EM, the first scanning line Gate_P are provided with a high level signal, the reset signal line Reset_N and the second scanning line Gate_N are provided with a low level signal, the first transistor T1, the second transistor T2, the fourth transistor T4, the fifth transistor T5, the sixth transistor T6 and the seventh transistor T7 are turned off, and a power supply signal provided by the power supply line VDD is written into the storage capacitor Cst.

In a second stage, the light-emitting control signal line EM, the reset signal line Reset_N, the first scanning line Gate_P are provided with a high-level signal, the second scanning line Gate_N is provided with a low-level signal, the second transistor T2, the fourth transistor T4, the fifth transistor T5, the sixth transistor T6 and the seventh transistor T7 are turned off, and an initialization signal provided by the initialization signal line Vinit is written into the storage capacitor Cst.

In a third stage, the light-emitting control signal line EM, the second scanning line Gate_N are provided with a high level signal, the first scanning line Gate_P and the reset signal line Reset_N are provided with a low level signal, the first transistor T1, the fifth transistor T5, the sixth transistor T6 and the seventh transistor T7 are turned off, the light-emitting element is initialized, and the power supply signal provided by the power supply line VDD is written into the storage capacitor Cst.

In a fourth stage, the light-emitting control signal line EM, the first scanning line Gate_P are provided with a high level signal, the second scanning line Gate_N, the reset signal line Reset_N are provided with a low level signal, and the first transistor T1, the second transistor T2, the fourth transistor T4, the fifth transistor T5, the sixth transistor T6 and the seventh transistor T7 are turned off.

In the fifth stage, the light-emitting control signal line EM, the reset signal line Reset_N and the second scanning line Gate_N are provided with a low level signal, the first scanning line Gate_P is provided with a high level signal, the first transistor T1 is turned off, the second transistor T2 is turned off, the fourth transistor T4 is turned off, the seventh transistor T7 is turned off, and the other transistors are turned on, and the light-emitting element emits light.

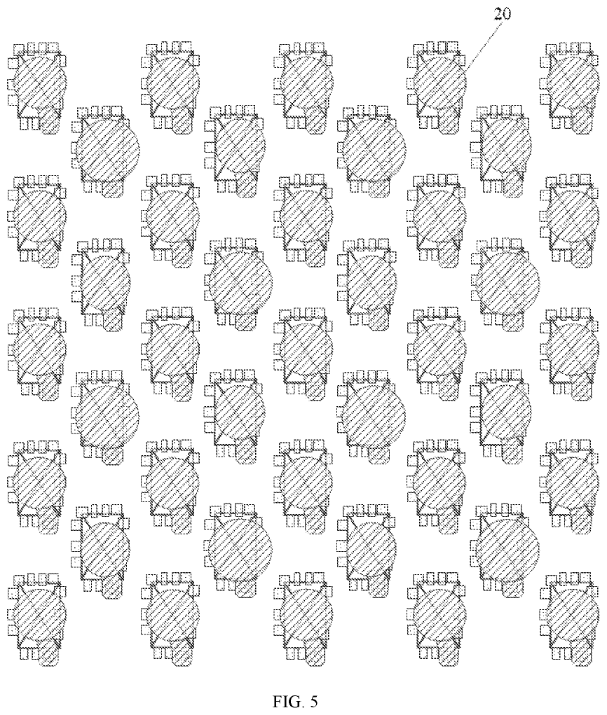

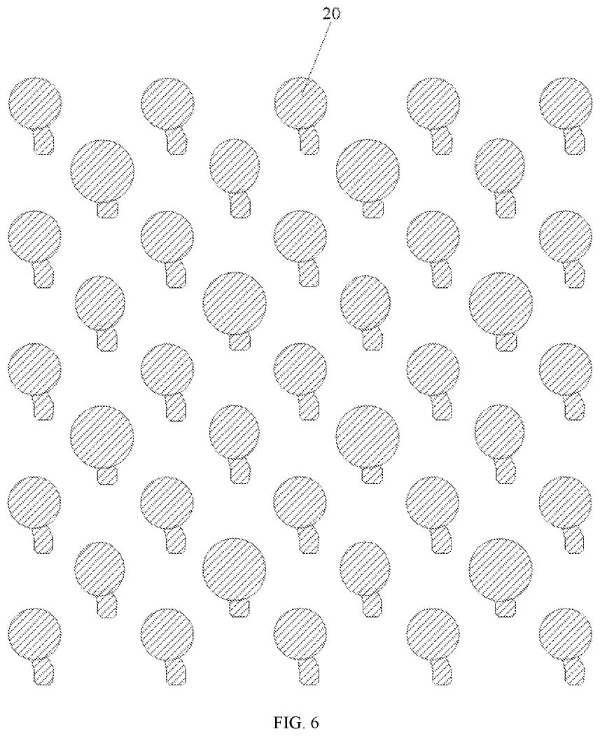

As shown in FIGS. 3 to 16, in some embodiments, a minimum spacing d1 between adjacent sub-pixel driving circuits 10 in a first direction is greater than or equal to a width d2 of one sub-pixel driving circuit 10 in the first direction. A minimum spacing d3 between adjacent sub-pixel driving circuits 10 in a second direction is greater than or equal to one half of a width d4 of one sub-pixel in the second direction. the first direction intersects with the second direction.

The adjacent sub-pixel driving circuits 10 in the first direction are electrically connected via a first signal line 40; and/or the adjacent sub-pixel driving circuits 10 in the second direction are electrically connected via a second signal line 41.

Illustratively, the plurality of sub-pixels are distributed as islands.

Illustratively, the size of the sub-pixel driving circuit 10 is compressed, and the plurality of sub-pixels are distributed as islands to form an isolated-islands pixel layout.

Illustratively, the spacing between the adjacent sub-pixel driving circuits 10 in the first direction is greater than or equal to one half of the width of one sub-pixel driving circuit 10 in the first direction.

Illustratively, the spacing between the adjacent sub-pixel driving circuits 10 in the second direction is greater than or equal to the width of one sub-pixel in the second direction.

Illustratively, the first signal line 40 and the second signal line 41 are made of an indium tin oxide (ITO) material.

In the above-mentioned arrangement, the plurality of sub-pixels are distributed as islands, which can increase the spacing between adjacent sub-pixels, and is advantageous for improving the transmittance.

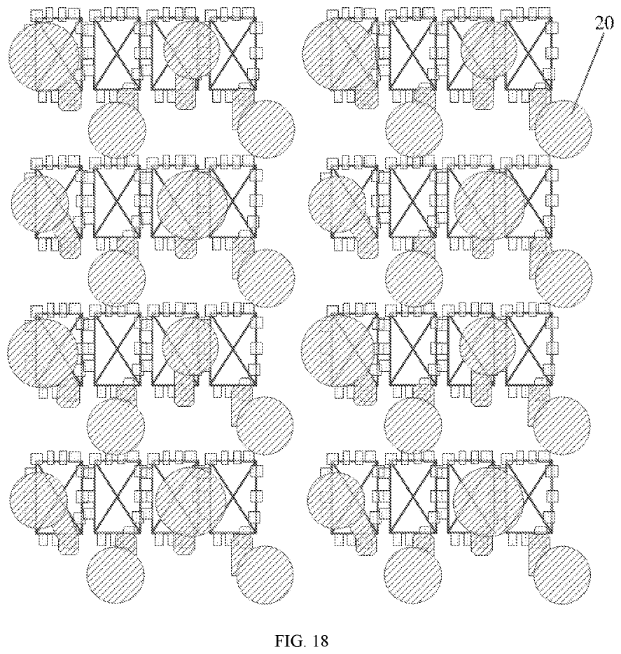

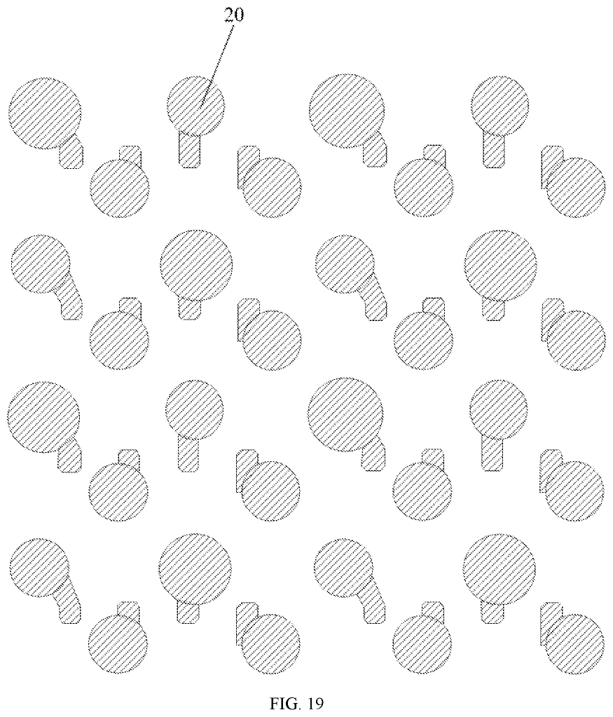

As shown in FIGS. 16-26, in some embodiments, the plurality of sub-pixels are divided into a plurality of sub-pixel groups 50 distributed in an array. Each sub-pixel group 50 includes at least two sub-pixels. The plurality of sub-pixel groups 50 are distributed as islands. A minimum distance d5 between two closest sub-pixel driving circuits 10 in adjacent sub-pixel groups 50 in the first direction is greater than or equal to a width d2 of one sub-pixel driving circuit 10 in the first direction. A minimum distance d6 between two closest sub-pixel driving circuits 10 in the adjacent sub-pixel groups 50 in the second direction is greater than or equal to one half of the width d4 of one sub-pixel in the second direction. The first direction intersects with the second direction.

The two closest sub-pixel driving circuits 10 in the adjacent sub-pixel groups 50 in the first direction are electrically connected via a first signal line 40; and/or the two closest sub-pixel driving circuits 10 in the adjacent sub-pixel groups 50 in the second direction are electrically connected via a second signal line 41.

Illustratively, four sub-pixels are included in each sub-pixel group 50, but the disclosure is not limited thereto.

Illustratively, a distance d7 between adjacent sub-pixel driving circuits 10 in the first direction in each sub-pixel group 50 is less than the distance d5 between two closest sub-pixel driving circuits 10 in the adjacent sub-pixel groups 50 in the first direction.

Illustratively, the sub-pixels are divided into the plurality of sub-pixel groups 50 distributed in an array, where each sub-pixel group 50 includes at least two sub-pixels, and the plurality of sub-pixel groups 50 are distributed as islands, forming a clustering pixel layout.

Illustratively, the distance d5 between the two closest sub-pixel driving circuits 10 in the adjacent sub-pixel groups 50 in the first direction is greater than or equal to one half of the width d2 of one sub-pixel driving circuit 10 in the first direction.

Illustratively, the distance d6 between the two closest sub-pixel driving circuits 10 in the adjacent sub-pixel groups 50 in the second direction is greater than or equal to the width d4 of one sub-pixel in the second direction.

In the above-mentioned arrangement, the plurality of sub-pixel groups 50 are distributed as islands, which can increase the spacing between adjacent sub-pixel groups 50, and is advantageous for improving the transmittance.

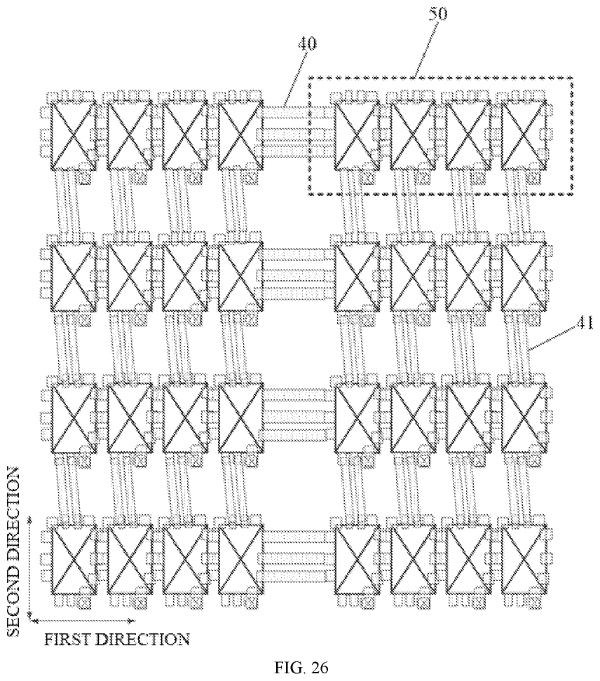

As shown in FIG. 26, in some embodiments, the first signal line 40 is a transparent signal line. The first signal line 40 includes at least one of: an initialization signal line Vinit and a gate line (such as at least one of a first scanning line Gate_P or a second scanning line Gate_N), a reset signal line Reset_N or a light-emitting control signal line EM. The second signal line 41 is a transparent signal line, which includes a data line Data and/or a power supply line VDD.

Illustratively, the initialization signal line Vinit includes at least a portion extending in the first direction. The first scanning line Gate_P includes at least a portion extending in the first direction. The second scanning line Gate_N includes at least a portion extending in the first direction. The reset signal line Reset_N includes at least a portion extending in the first direction. The light-emitting control signal line EM includes at least a portion extending in the first direction.

As shown in FIG. 8, in some embodiments, the plurality of pixel definition patterns PDL are independent of one another.

In the above-mentioned arrangement, the plurality of pixel definition patterns PDL are arranged to be independent from each other, so that there is a spacing region 60 between adjacent pixel definition patterns PDL. This is advantageous for improving the transmittance of the display substrate. Furthermore, with the above-mentioned arrangement, the pixel definition pattern PDL can independently shield the sub-pixel driving circuit 10 corresponding thereto. By arranging the pixel definition pattern PDL to have an appropriate shape and appropriately increasing the area of the pixel definition pattern PDL, an optimized shielding for the sub-pixel driving circuit 10 can be achieved, thereby reducing the reflectivity of the UDC region.

As shown in FIGS. 13 and 21, in some embodiments, at least some of the plurality of pixel definition patterns PDL are formed as a one-piece structure.

With the above-mentioned arrangement, the layout space can be used more reasonably, and an optimized shielding for the sub-pixel driving circuit 10 can be achieved while ensuring the transmittance, thereby reducing the reflectivity of the UDC region.

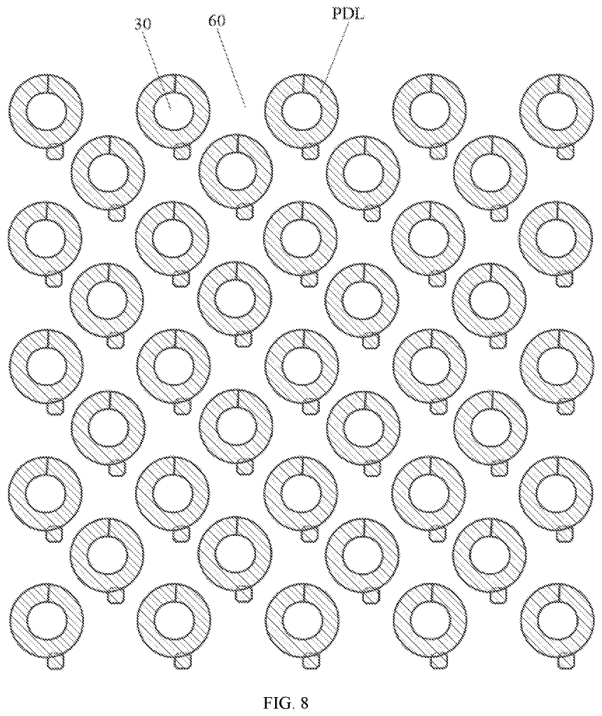

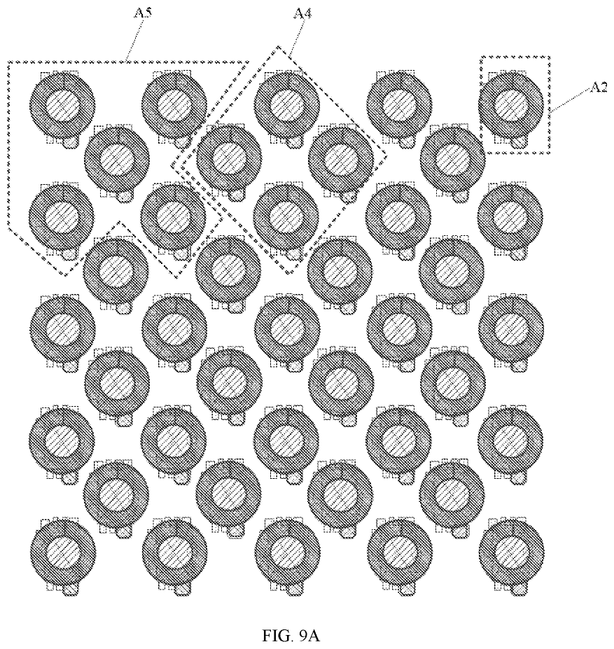

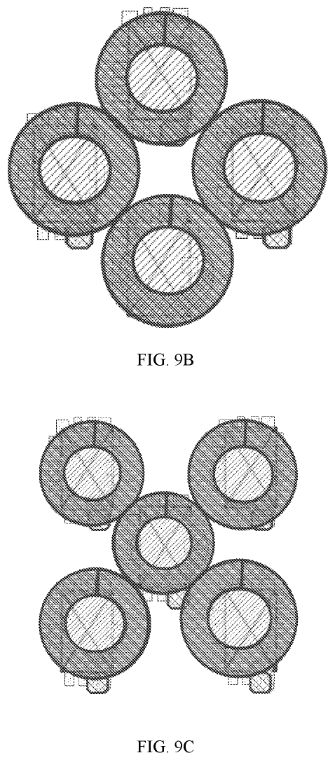

As shown in FIG. 9b and FIG. 9c, some of the plurality of pixel definition patterns PDL are formed as a one-piece structure.

It is to be noted that the structure in FIG. 9a may be modified in accordance with the structure illustrated in FIGS. 9b and 9c, i.e., the plurality of pixel definition patterns PDL are divided into a plurality of groups, such as four pixel definition patterns per group or five pixel definition patterns per group. Pixel definition patterns PDL belonging to the same group are formed as a one-piece structure.

Illustratively, the arrangement of the black matrices BM may be substantially the same as that of the pixel definition patterns PDL, i.e., the black matrices BM may also be divided into a plurality of groups, such as four black matrices per group or five black matrices per group. Black matrices BM belonging to the same group are formed as a one-piece structure.

As shown in FIGS. 13 and 21, in some embodiments, in the at least some of the pixel definition pattern PDL formed as the one-piece structure, there is a spacing region 60 between adjacent pixel definition patterns PDL, an orthographic projection of a boundary of the spacing region 60 onto the base substrate surrounds at least a portion of the first signal line 40 and/or at least a portion of the second signal line 41 in the display substrate.

In the display substrate provided by the above-mentioned embodiments, the transmittance of the display substrate can be improved by arranging the spacing region 60 between the adjacent pixel definition patterns PDL. Furthermore, by arranging the orthographic projection of the boundary of the spacing region 60 onto the base substrate to surround at least a portion of the first signal line 40 and/or at least a portion of the second signal line 41 in the display substrate, so that the electrical connection between adjacent sub-pixel driving circuits 10 can be realized with the first signal line 40 and the second signal line 41 in a region which is not shielded by the pixel definition layer, thereby ensuring the transmittance of the display substrate.

As shown in FIGS. 12-16, in some embodiments, an orthographic projection of an outer boundary of the pixel definition pattern PDL onto the base substrate is rectangular.

In some embodiments, an orthographic projection of an outer boundary of the pixel definition pattern PDL onto the base substrate is circular.

In some embodiments, at least a portion of the orthographic projection of the outer boundary of the pixel definition pattern PDL onto the base substrate is annular.

In some embodiments, the orthographic projection of the outer boundary of the pixel definition pattern PDL onto the base substrate has a non-regular shape.

In some embodiments, the plurality of pixel definition patterns includes at least two types of pixel definition patterns having different shapes. As shown in FIG. 30, illustratively, an orthographic projection of an outer boundary of one of some pixel definition patterns PDL onto the base substrate is rectangular and an orthographic projection of an outer boundary of one of remaining pixel definition patterns PDL onto the base substrate is at least partially annular. The rectangular pixel definition layer PDL and the annular pixel definition layer PDL may be independent from each other, or be formed as a one-piece structure.

In the above-mentioned arrangement, the layout space can be used more reasonably, and the sub-pixel driving circuit 10 can be shielded in a better way while ensuring the transmittance, thereby reducing the reflectivity of the UDC region.

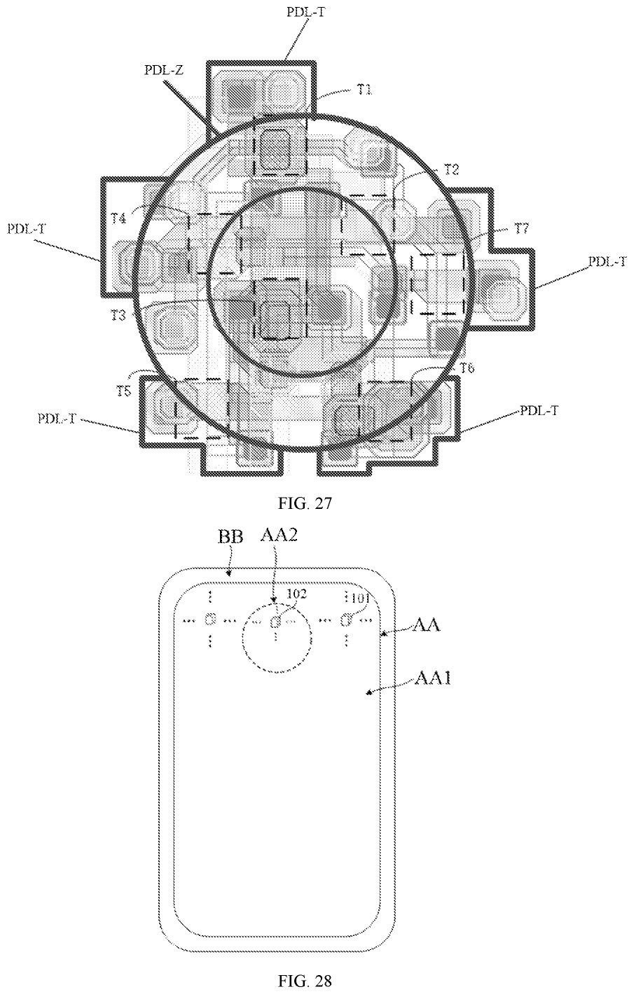

As shown in FIG. 27, in some embodiments, the pixel definition pattern PDL includes a pixel definition main body portion PDL-Z and at least one pixel definition protruding portion PDL-T. The pixel definition protruding portion PDL-T is coupled with the pixel definition main body portion PDL-Z, an overlapping area between an orthographic projection of the pixel definition main body portion PDL-Z onto the base substrate and an orthographic projection of a corresponding sub-pixel driving circuit 10 onto the base substrate, is greater than an overlapping area between an orthographic projection of the pixel definition protruding portion PDL-T onto the base substrate and the orthographic projection of the corresponding sub-pixel driving circuit 10 onto the base substrate.

Illustratively, the pixel definition main body portion and the pixel definition protruding portion are formed as a one-piece structure.

Illustratively, the pixel definition main body portion includes a regular pattern such as a rectangle, a ring, etc. The pixel-defining protrusion portion may have a non-regular shape, but the present disclosure is not limited thereto.

Illustratively, the pixel definition main body portion can cover a large portion of the sub-pixel driving circuit 10, and the pixel-defining protrusion portion can cover a small portion located at the periphery of the large portion.

In the display substrate provided by the above-mentioned embodiment, the pixel definition pattern PDL includes the pixel definition main body portion and at least one the pixel definition protruding portion, and the pixel definition main body portion can cover a portion of the sub-pixel driving circuit 10 having a relatively regular, large area in the sub-pixel driving circuit 10, and the pixel definition protruding portion can cover a protruding portion of the sub-pixel driving circuit 10 having a relatively small area which is located at the periphery of the above-mentioned portion of the sub-pixel driving circuit 10. In this way, not only an optimized shielding for the sub-pixel driving circuit 10 can be achieved, but also an area occupied by the pixel definition pattern PDL can be minimized, thereby effectively ensuring the transmittance and reflectance of the display substrate.

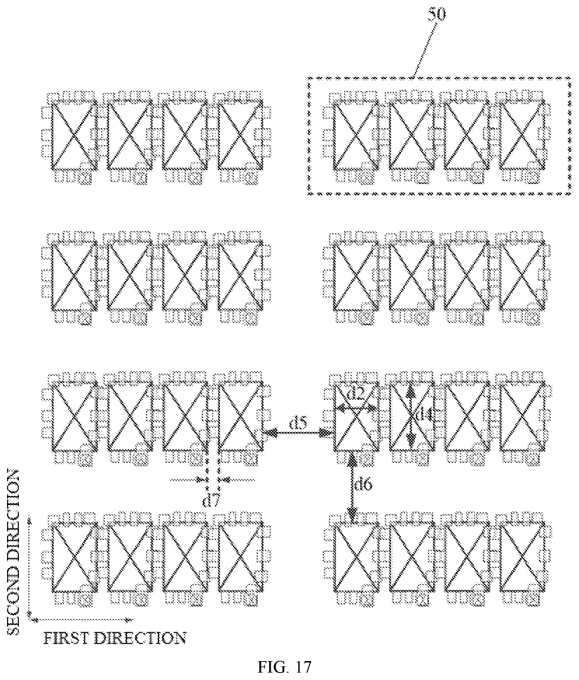

As shown in FIGS. 17 to 22, in some embodiments, the sub-pixel driving circuits 10 included in the sub-pixel group 50 are arranged along the first direction.

Pixel definition patterns PDL corresponding to sub-pixel driving circuits 10 in the same sub-pixel group 50 are formed as a one-piece structure, and the pixel definition patterns PDL formed as the one-piece structure covers at least a portion of a region located between adjacent sub-pixel driving circuits 10.

Illustratively, in the same sub-pixel group 50, the pixel definition pattern PDL corresponding to the sub-pixel driving circuits 10 are formed as the one-piece structure, and the pixel definition patterns PDL formed as the one-piece structure fully covers the region located between the adjacent sub-pixel driving circuits 10.

In the display substrate provided in the above-mentioned embodiment, the pixel definition patterns PDL corresponding to the sub-pixel driving circuits 10 in the same sub-pixel group 50 is arranged to be the one-piece structure, and the pixel definition patterns PDL formed as the one-piece structure is arranged to cover at least a portion of the region located between adjacent sub-pixel driving circuits 10. In this way, not only an optimized shielding for the sub-pixel driving circuit 10 can be achieved, but also an area occupied by the pixel definition pattern PDL can be minimized, thereby effectively ensuring the transmittance and reflectance of the display substrate.

As shown in FIGS. 17 to 22, in some embodiments, in sub-pixel groups 50 located in the same column in the second direction, pixel definition patterns PDL corresponding to sub-pixel driving circuits 10 are formed as a one-piece structure.

The above-mentioned arrangement not only enables a better shielding for the sub-pixel driving circuit 10, but also minimizes an area occupied by the pixel definition pattern PDL, thereby effectively ensuring the transmittance and reflectance of the display substrate.

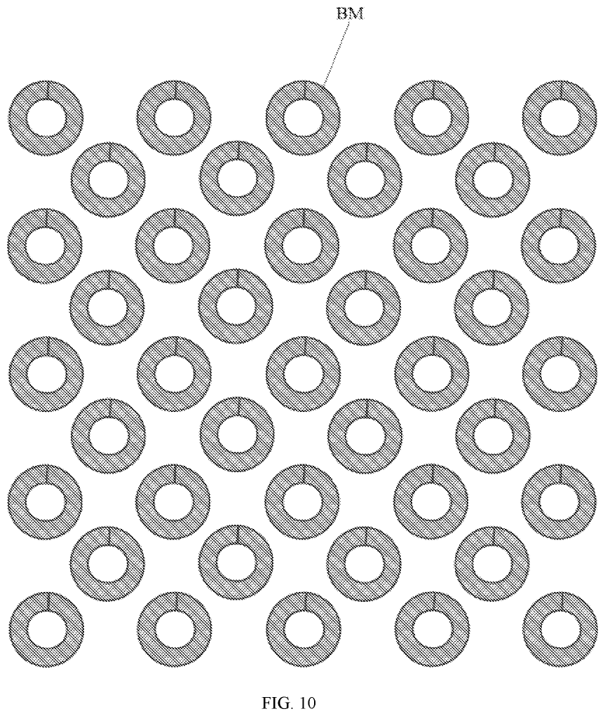

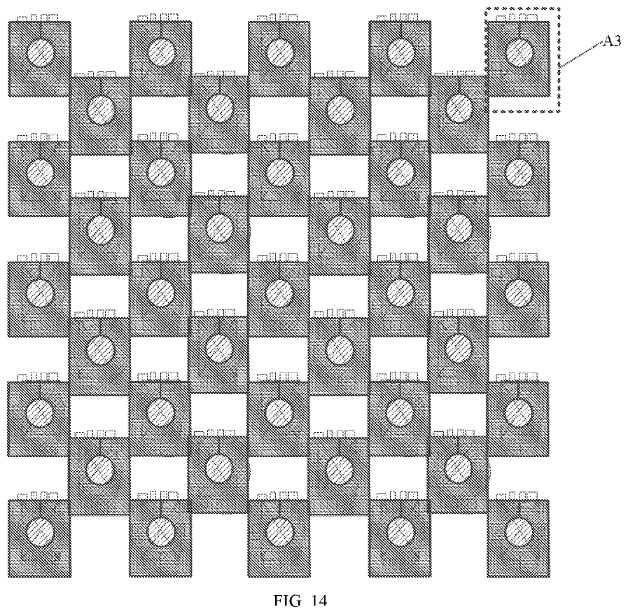

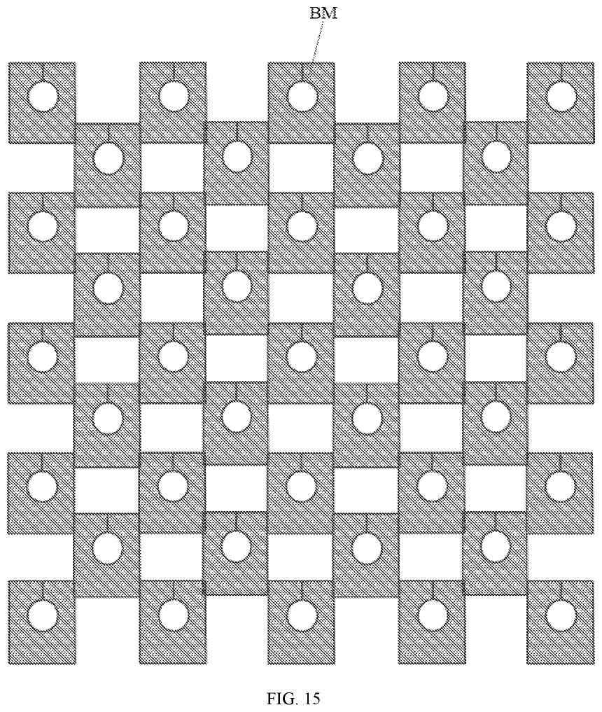

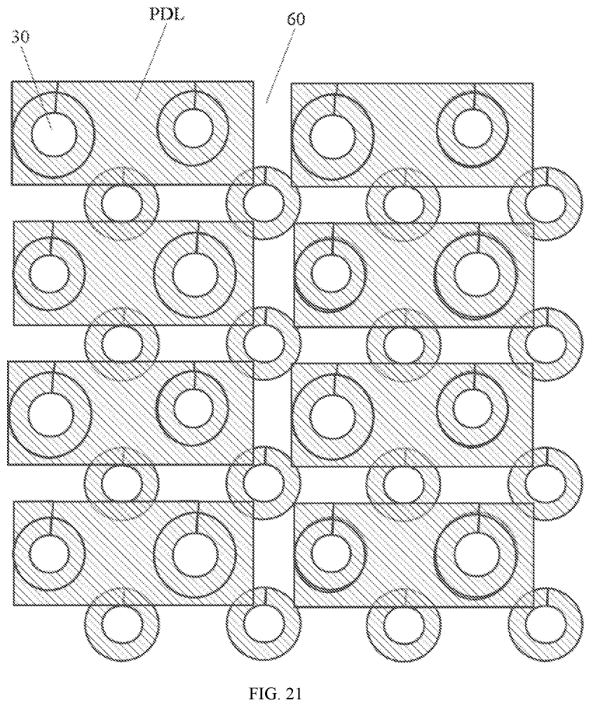

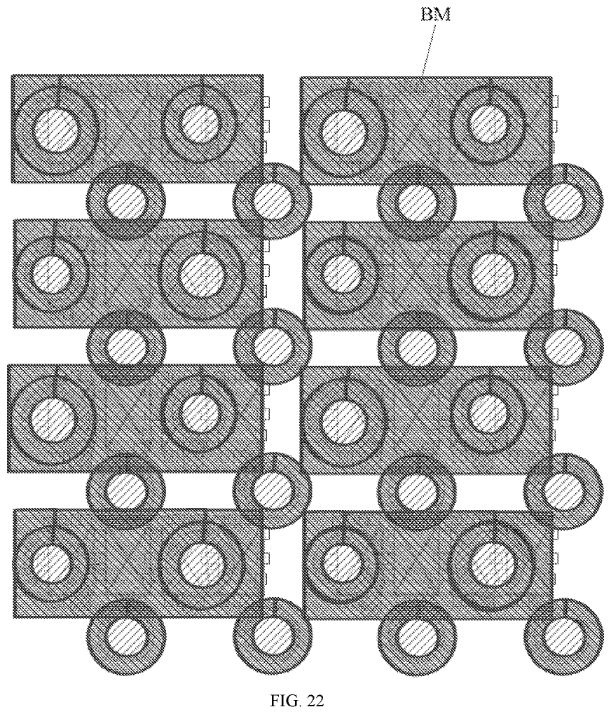

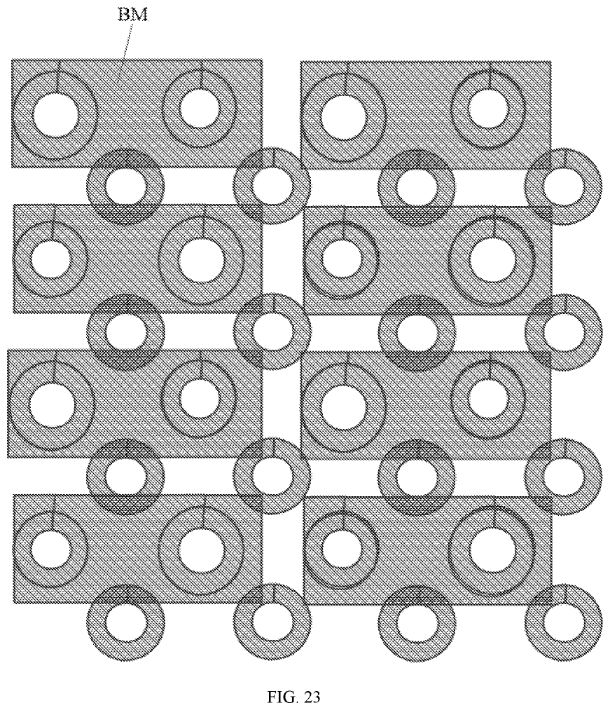

As shown in FIG. 9a, FIG. 10, FIG. 11, FIG. 14, FIG. 15, FIG. 16, FIG. 22 and FIG. 23, in some embodiments, the display substrate further includes an encapsulation layer and a plurality of black matrix patterns BM. The encapsulation layer is located between the plurality of black matrix patterns BM and the base substrate, an orthographic projection of a black matrix pattern BM onto the base substrate at least partially overlaps with an orthographic projection of a corresponding pixel definition pattern PDL onto the base substrate.

As shown in FIG. 31, exemplarily, the display substrate further includes a plurality of color film patterns (CF) and a plurality of black matrix patterns (BM). The plurality of color film patterns (CF) and the plurality of black matrix patterns (BM) are both located on a side of the encapsulation layer facing away from the base substrate. The color film patterns (CF) and the black matrix patterns (BM) are located on the same surface, and one black matrix pattern (BM) is arranged between adjacent color film patterns. Illustratively, the color film patterns include a red color film pattern, a green color film pattern, and a blue color film pattern, but the present disclosure is not limited thereto.

Illustratively, the display substrate further includes a touch control structure, the touch control structure is located at a side of the encapsulation layer facing away from the base substrate, and the plurality of color film patterns and the plurality of black matrix patterns BM are both located on the side of the touch control structure facing away from the base substrate. The display substrate further includes a planarization layer and a cover plate, the planarization layer is located between the cover plate and the black matrix patterns BM as well as the color film patterns.

Illustratively, the plurality of black matrix patterns BM are distributed in an array, and there is a spacing region between adjacent black matrix patterns BM.

Illustratively, in the display substrate provided in the above-mentioned embodiment, by arranging the display substrate to further include the black matrix patterns BM and the color film patterns, the COE (Color On Encapsulation) technology is used in the display substrate, which can improve a displaying contrast of the display substrate.

In the display substrate provided in the above-mentioned embodiment, by arranging the orthographic projection of the black matrix pattern BM onto the base substrate at least partially overlaps with the orthographic projection of the corresponding pixel definition layer onto the base substrate, not only the pixel aperture 30 included in the display substrate is prevented from being shielded by the black matrix pattern BM, but also the black matrix pattern BM can absorb ambient light. In this way, an optimized aperture ratio, light transmittance and reflectivity of the display substrate can be ensured.

As shown in FIG. 8, FIG. 9a, FIG. 10, FIG. 11, FIG. 13, FIG. 14, FIG. 15, FIG. 16, FIG. 21, FIG. 22 and FIG. 23, in some embodiments, a contour of the orthographic projection of the black matrix pattern BM onto the base substrate is substantially the same as a contour of the orthographic projection of the corresponding pixel definition pattern PDL onto the base substrate.

Illustratively, an orthographic projection of an outer boundary of the black matrix pattern BM onto the base substrate is rectangular.

Illustratively, the orthographic projection of the outer boundary of the black matrix pattern BM onto the base substrate is circular.

Illustratively, the orthographic projection of the outer boundary of the black matrix pattern BM onto the base substrate is annular.

Illustratively, the orthographic projection of the outer boundary of the black matrix pattern BM onto the base substrate has a non-regular shape.

The above-mentioned arrangement can enable the orthographic projection of the black matrix pattern BM onto the base substrate and the orthographic projection of the corresponding pixel definition pattern PDL onto the base substrate to be substantially overlapped with each other, which not only prevents the pixel aperture 30 included in the display substrate from being shielded by the black matrix pattern BM, but also enables the black matrix pattern BM to absorb ambient light. In this way, an optimized aperture ratio, light transmittance and reflectivity of the display substrate can be ensured.

As shown in FIGS. 11 and 16, in some embodiments, an orthographic projection of an inner boundary of the black matrix pattern onto the base substrate enclose an orthographic projection of an inner boundary of a corresponding pixel definition pattern PDL onto the base substrate.

The above-mentioned arrangement not only prevent the pixel aperture 30 included in the display substrate from being shielded by the black matrix pattern BM, but also enables the black matrix pattern BM to absorb ambient light. In this way, an optimized aperture ratio, light transmittance and reflectivity of the display substrate can be ensured.

As shown in FIGS. 11 and 16, in some embodiments, an orthographic projection of an outer boundary of the pixel definition pattern PDL onto the base substrate encloses an orthographic projection of a corresponding black matrix pattern onto the base substrate.

The above-mentioned arrangement enables the orthographic projection of the black matrix pattern BM onto the base substrate to be fully located inside the orthographic projection of the pixel definition pattern PDL onto the base substrate. In this way, the black matrix pattern BM can be prevented from affecting the light exiting rate of the display substrate, thereby effectively ensuring the light exiting rate of the display substrate.

As shown in FIG. 28, in some embodiments, the display substrate includes a display region AA and a peripheral region BB surrounding the display region AA. The display region AA includes a first display region AA1 and a second display region AA2, the first display region AA1 is located at least at one side of the second display region AA2.

The plurality of sub-pixels includes a plurality of first sub-pixels 101 and a plurality of second sub-pixels 102. the plurality of first sub-pixels 101 is located in the first display region AA1 and the plurality of second sub-pixels 102 is located in the second display region AA2, a pixel density of the plurality of second sub-pixels 102 is less than or equal to a pixel density of the plurality of first sub-pixels 101, the plurality of pixel definition patterns is located in the second display region AA2.

Illustratively, a light transmittance of the first display region AA1 is less than a light transmittance of the second display region AA2.

Illustratively, the second display region includes a light sensing element, such as a camera, a photosensitive sensor, etc.

Illustratively, the first display region encloses the second display region, or the second display region is located at one side of the first display region, but this is not limiting.

Illustratively, the first display region is a normal display region and does not include a camera structure.

Illustratively, the second display region includes a circular display region, a square display region, etc.

Illustratively, a pixel size (including length and width) of the sub-pixel driving circuit 10 included in the second display region may be one half of a pixel size of the sub-pixel driving circuit 10 included in the first display region, but the present disclosure is not limited thereto.

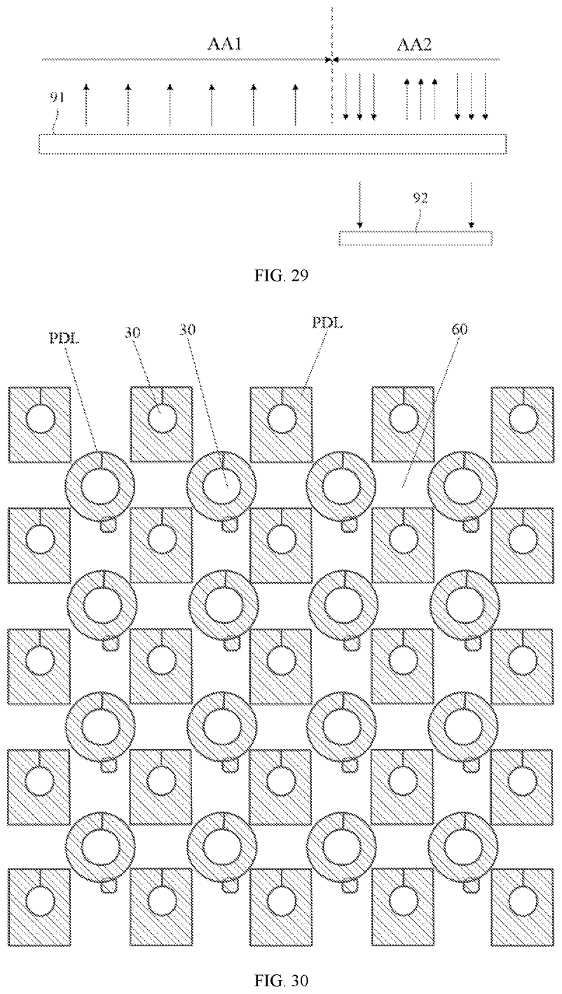

As shown in FIG. 29, FIG. 29 illustrates that the transmittance of the second display region AA2 where the photosensitive sensor 92 is located is higher than the transmittance of the first display region AA1, and FIG. 29 also illustrates a screen 91 of the display substrate.

In the display substrate provided by the above-mentioned embodiment, the transmittance of the second display region can be effectively improved, so as to improve the display quality of the display substrate.

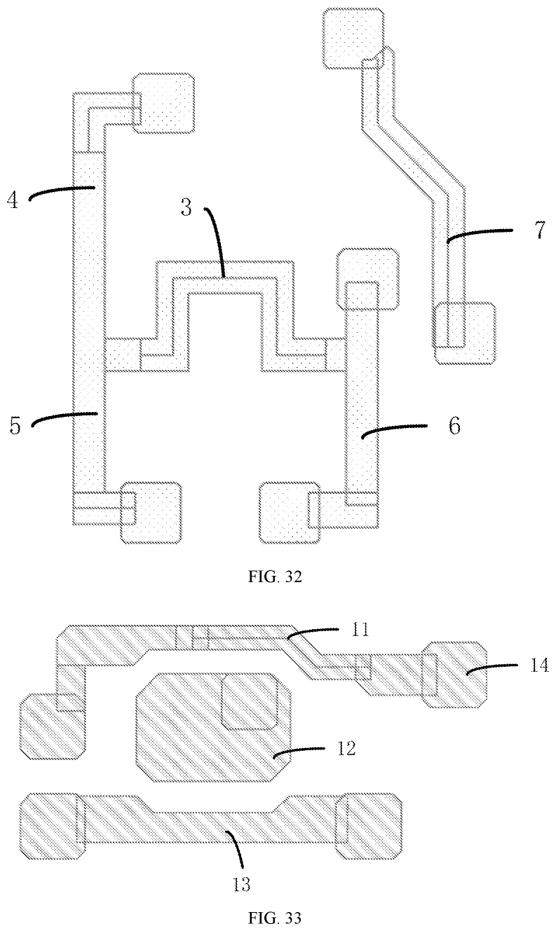

As shown in FIG. 32 to FIG. 60, some of a manufacturing process of a sub-pixel driving circuit proceeds is described hereinafter.

A polysilicon layer, namely, a first active layer, is deposited. A structure as shown in FIG. 32 is formed after patterning the polysilicon layer. The structure includes a third channel line 3, a fourth channel line 4, a fifth channel line 5, a sixth channel line 6 and a seventh channel line 7, in which the third channel line 3 is used for forming T3, the fourth channel line 4 is used for forming T4, the fifth channel line 5 is used for forming T5, the sixth channel line 6 is used for forming T6 and the seventh channel line 7 is used for forming T7.

A first gate metal layer is deposited. The first gate metal layer is patterned to form a structure shown in FIG. 33, which includes a third gate electrode line 11, a first electrode plate 12 and a sixth gate electrode line 13. FIG. 34 is a schematic view showing the polysilicon layer and the first gate metal layer are overlapped. The third gate electrode line 11 is overlapped with the fourth channel line 4 to form T4, and the third gate electrode line 11 is overlapped with the seventh channel line 7 to form T7. The third gate electrode line 11 serves as a top gate electrode of T4 and a top gate electrode of T7. The first electrode plate 12 is used to form an electrode plate of a storage capacitor, and T3 is formed at a position where the first electrode plate 12 and the third channel line 3 are overlapped. The sixth gate electrode line 13 is overlapped with the fifth channel line 5 to form T5, and the sixth gate electrode line 13 is overlapped with the sixth channel line to form T6, and the sixth gate electrode line 13 is used to form top gate electrodes of T5 and T6. An end of the third gate electrode line 11 is provided with a first bonding pad 14.

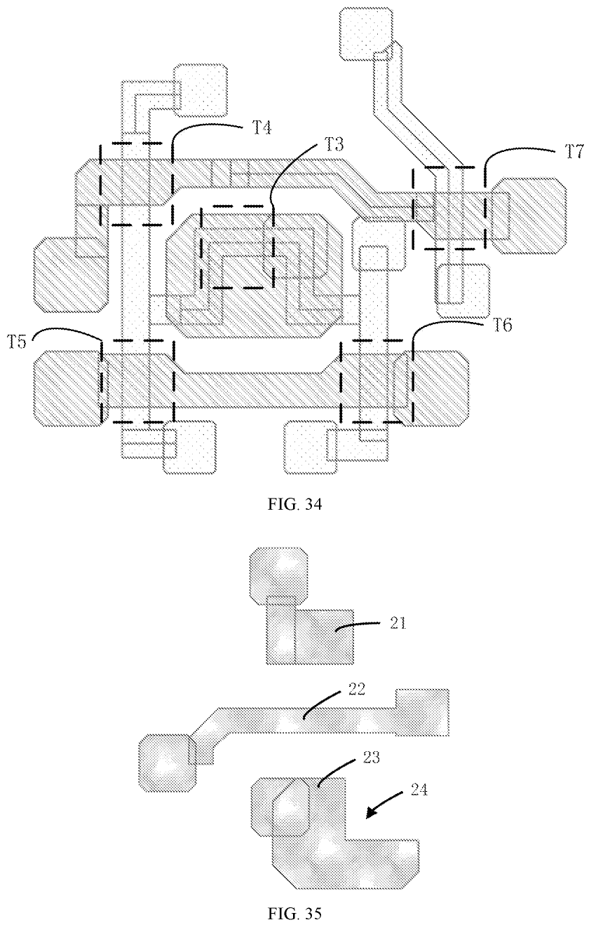

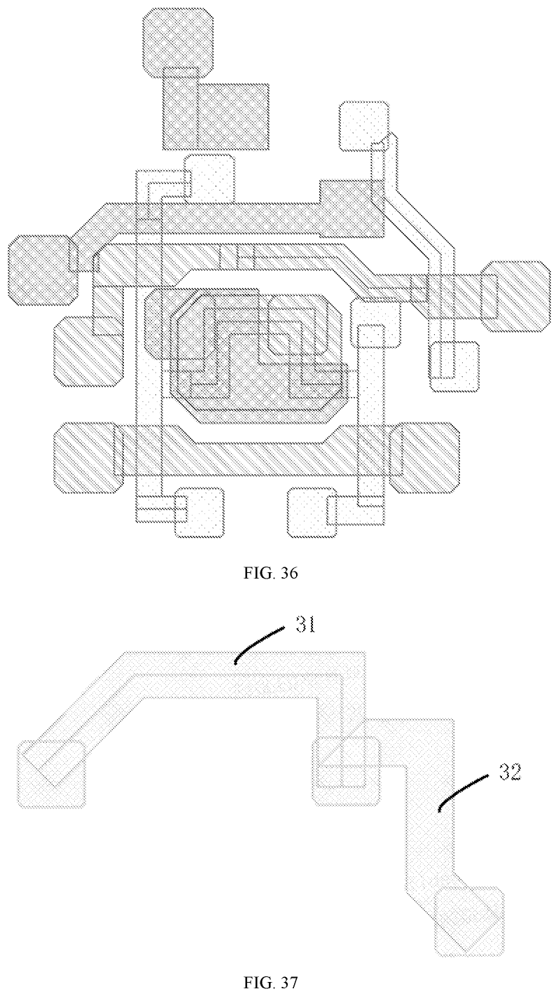

A second gate metal layer is deposited. The second gate metal layer is patterned to form a structure as shown in FIG. 35, which includes first gate electrode line 21, a fourth gate electrode line 22 and a second electrode plate 23, where the second electrode plate is provided with a notch structure 24. The first gate electrode line 21 is used for forming a bottom gate electrode of T1, the fourth gate electrode line 22 is used for forming a bottom gate electrode of T2, and the second electrode plate 23 and the first electrode plate 12 form the storage capacitor Cst. FIG. 36 is a schematic view showing the structure after the second gate metal layer is stacked thereon.

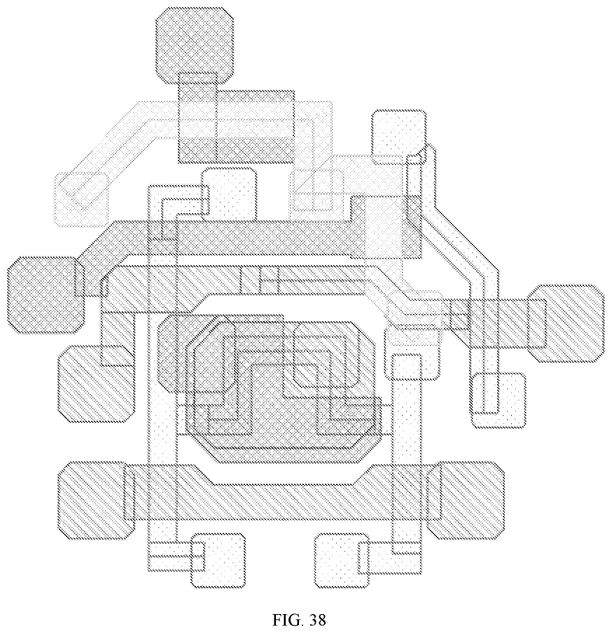

A metal oxide layer, namely, a second active layer, is deposited. The layer is patterned to form a structure shown in FIG. 37, which includes a first channel line 31 and a second channel line 32, where the first channel line 31 is used for forming T1, and the second channel line 32 is used for forming T2. The first channel line 31 and the second channel line 32 are connected. FIG. 38 is a schematic view showing the structure after a low temperature polycrystalline oxide layer is provided thereon.

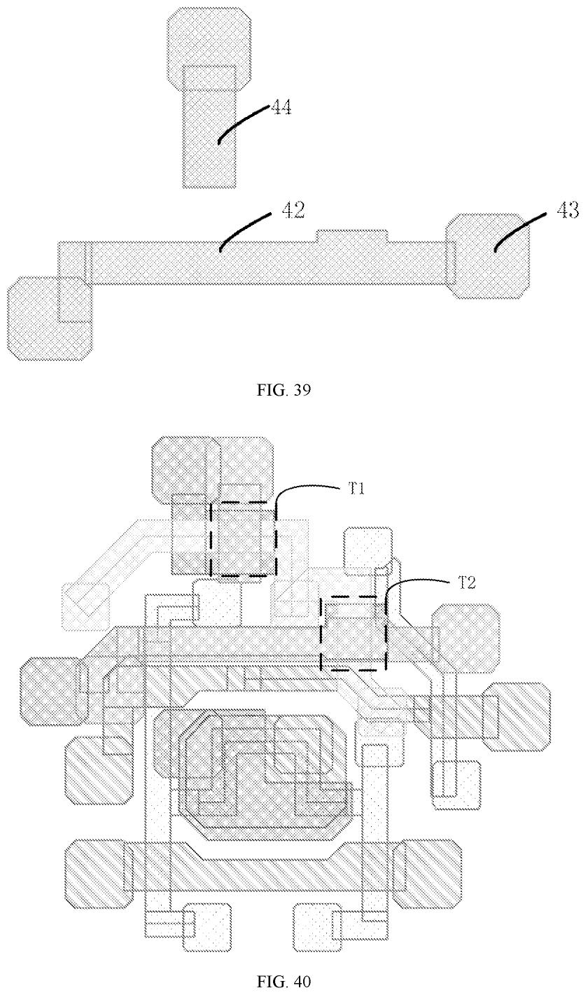

A third gate metal layer is deposited. The third gate metal layer is patterned to form a structure shown in FIG. 39, which includes a second gate electrode line 44 and a fifth gate electrode line 42, where the second gate electrode line 44 is used for forming a top gate electrode of T1, and the fifth gate electrode line 42 is used for forming a top gate electrode of T2. An end of the fifth gate electrode line is provided with a second bonding pad 43. FIG. 40 is a schematic view showing the structure after the third gate metal layer is provided thereon.

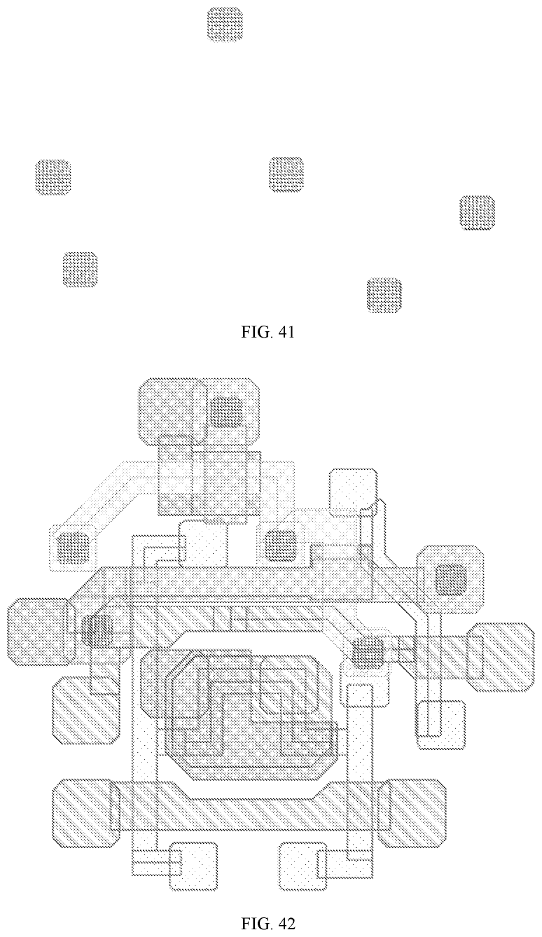

A first interlayer insulating layer is deposited. FIG. 41 is a diagram showing a mask for the first interlayer insulating layer, and FIG. 42 is a schematic view showing the structure after the first interlayer insulating layer is provided thereon, which illustrates via holes formed in the first interlayer insulating layer.

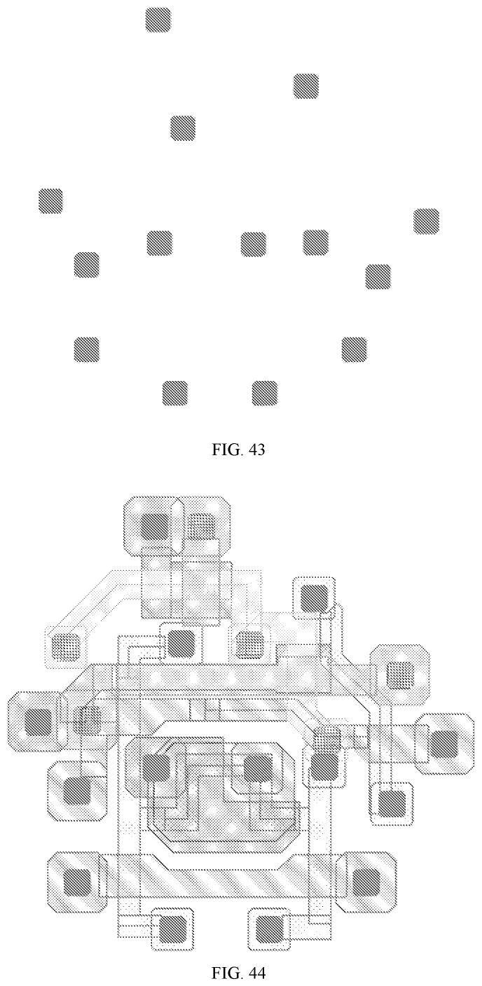

A second interlayer insulating layer is deposited. FIG. 43 is a diagram showing a mask for the second interlayer insulating layer, and FIG. 44 is a schematic view showing the structure after the second interlayer insulating layer is provided thereon, which illustrates via holes formed in the second interlayer insulating layer.

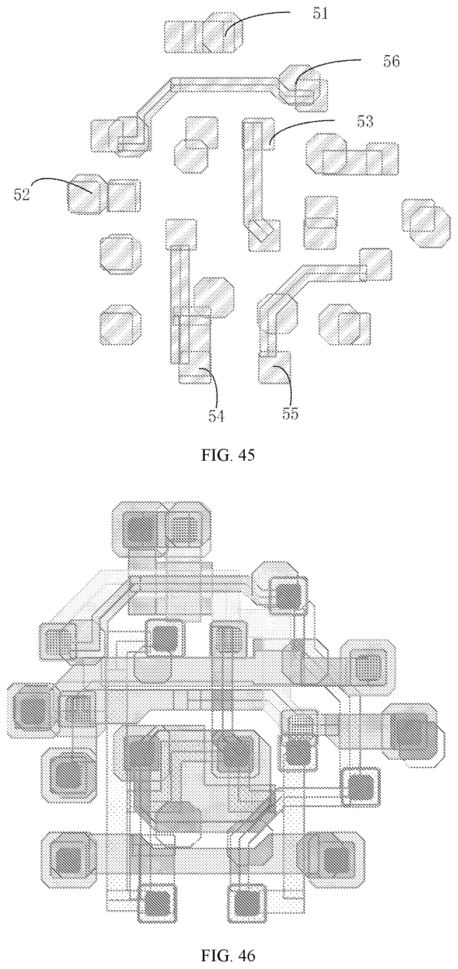

A first source and drain metal layer is deposited. FIG. 45 is a schematic structural diagram for the first source and drain metal layer, where the first source and drain metal layer includes a first bonding line 51, and the first bonding line 51 is connected to the first gate electrode line 21 and the second gate electrode line 41 through via holes formed in the first interlayer insulating layer and the second interlayer insulating layer.

The first source and drain metal layer further includes an opaque initialization section 56 of an initialization signal line Vinit, and the opaque initialization section 56 is connected to the first channel line 31 and the seventh channel line 7 through via holes formed in the first interlayer insulating layer and the second interlayer insulating layer.

The first source and drain metal layer further includes a second bonding line 52, and the second bonding line 52 is connected to the fourth gate electrode line 22 and the fifth gate electrode line 42 through via holes formed in the first interlayer insulating layer and the second interlayer insulating layer.

The first source and drain metal layer further includes a third bonding line 53, one end of the third bonding line 53 is connected to the first electrode plate 12 through via holes formed in the first interlayer insulating layer and the second interlayer insulating layer, passing through the notch structure 24. Another other end of the third bonding line 53 is connected to the first channel line 31 and the second channel line 32 through via holes formed in the first interlayer insulating layer and the second interlayer insulating layer.

The first source and drain metal layer further includes a fourth bonding line 54, one end of the fourth bonding line 54 is connected to the fifth channel line 5, and another end of the fourth bonding line 54 is connected to the second electrode plate 23.

The first source and drain metal layer further includes a fifth bonding line 55 for connecting the sixth channel line 6 and the seventh channel line 7.

FIG. 46 is a schematic view showing the structure after the first source and drain metal layer provided thereon.

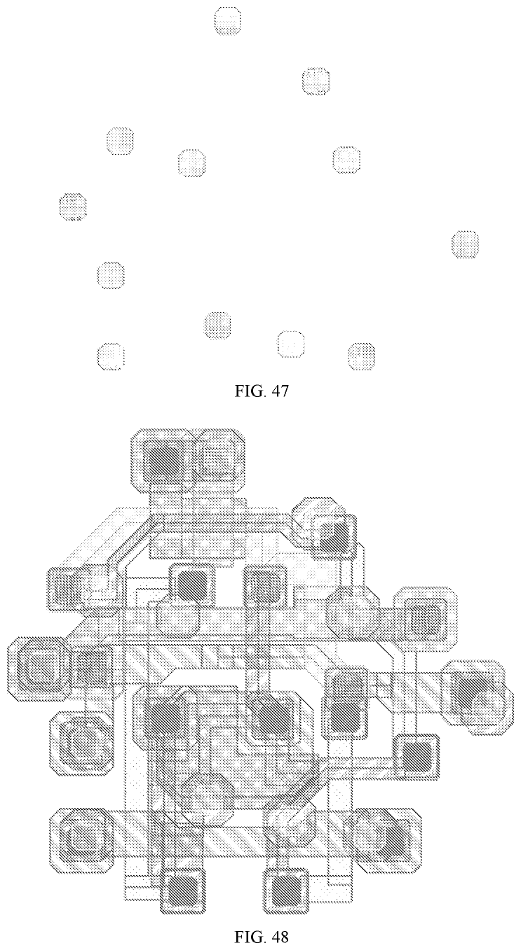

A passivation layer is deposited. FIG. 47 is a diagram of a mask for the passivation layer, and FIG. 48 is a schematic view of the structure after the passivation layer is provided thereon, which illustrates via holes formed in the passivation layer.

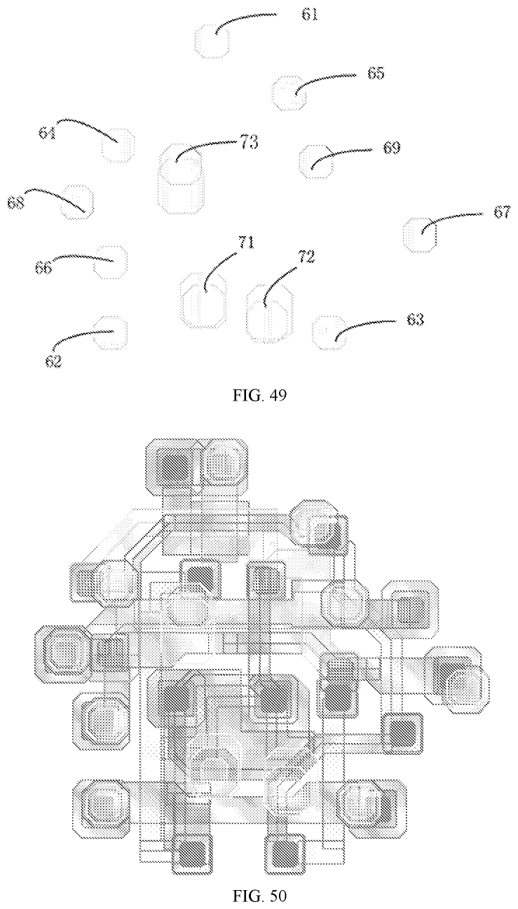

A first ITO layer, i.e., a first transparent conductive layer, is deposited. The first ITO layer includes a first connection line and a bonding structure for the first connection line and the sub-pixel driving circuit. FIG. 49 is the bonding structure in the first ITO layer.

The first ITO layer includes a first bonding structure 61 connected to the first bonding line 51, the first bonding structure 61 and at least one first connection line are formed as a one-piece structure.

The first ITO layer further includes a second bonding structure 62 located at one end of the sixth gate electrode line 13, and a third bonding structure 63 located at the other end of the sixth gate electrode line 13. Another first connecting line, the second bonding structure 62 and the third bonding structure 63 are formed as a one-piece structure, and this first connecting line is connected to the sixth gate electrode line 13 via the second bonding structure 62 and the third bonding structure 63.

The first ITO layer further includes a fourth bonding structure 64 located at one end of the initialization signal line and a fifth bonding structure 65 located at the other end of the initialization signal line, and one first connecting line is connected to the initialization signal line via the fourth bonding structure 64 and the fifth bonding structure 65.

The first ITO layer further includes a sixth bonding structure 66 located at one end of the third gate electrode line 11 and a seventh bonding structure 67 located at the other end of the third gate electrode line 11, and one first connection line is connected to the third gate electrode line 11 via the sixth bonding structure 66 and the seventh bonding structure 67.

The first ITO layer further includes an eighth bonding structure 68 at one end of the fifth gate electrode line 42 and a ninth bonding structure 69 at the other end of the fifth gate electrode line 42, and one first connection line is connected to the fifth gate electrode line 42 via the eighth bonding structure 68 and the ninth bonding structure 69.

The first ITO layer further includes a tenth bonding structure 73 connected to the channel line of T4.

The first ITO layer further includes an eleventh bonding structure 71 connected to the fourth bonding line 54.

The first ITO layer also includes a twelfth bonding structure 72 connected to the fifth bonding line 55.

FIG. 50 is a schematic view showing the structure after the first ITO layer is provided thereon.

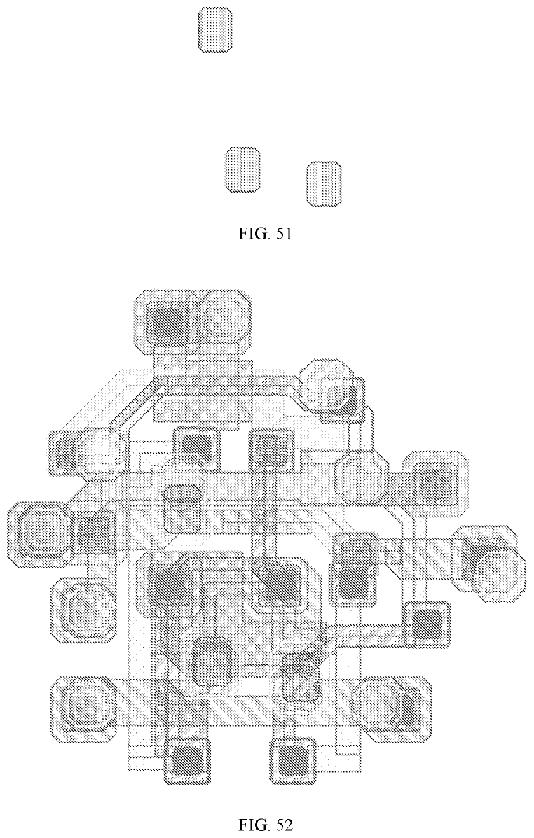

A basic planarization layer is deposited. FIG. 51 is a diagram of a mask for the basic planarization layer, and FIG. 52 is a schematic view showing the structure after the basic planarization layer is provided thereon, which illustrates via holes formed in the basic planarization layer.

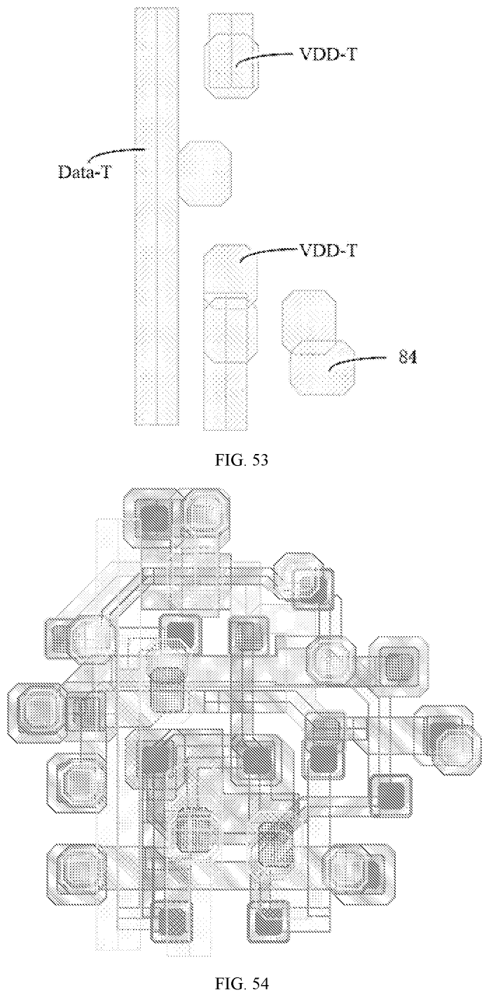

A second layer of ITO is deposited. The second ITO layer includes a transparent power supply portion VDD-T, a transparent data line Data-T, and a connection structure 84. The transparent data line Data-T is connected to the tenth bonding structure 73, a first end of the transparent power supply part VDD-T is connected to the eleventh bonding structure 71, and a second end of the transparent power supply part VDD-T is connected to a second source and drain metal layer. FIG. 53 shows the second ITO layer, and FIG. 54 a schematic view showing the structure after the second ITO layer is provided thereon.

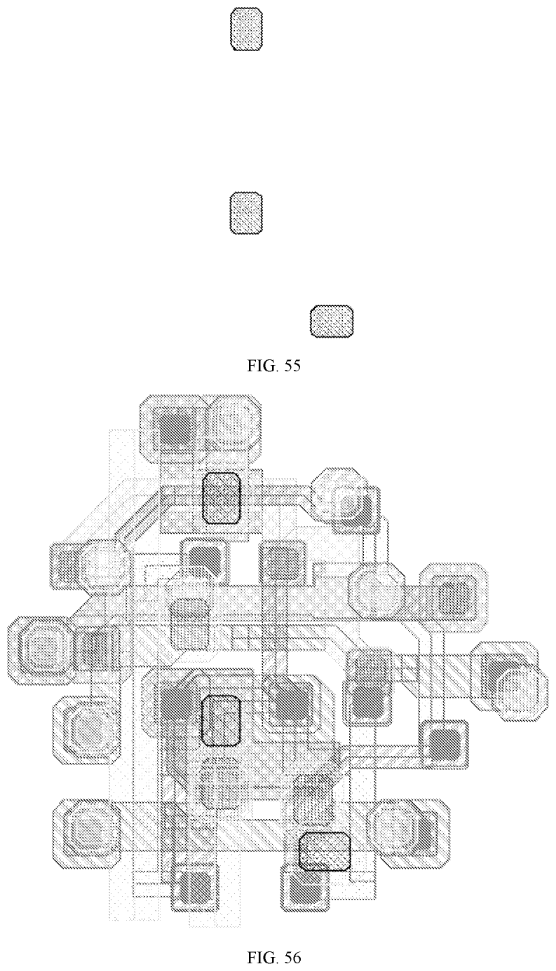

A first planarization layer is deposited. FIG. 55 is a diagram of a mask for the first planarization layer, and FIG. 56 is a schematic view showing the structure after the first planarization layer is provided thereon, which illustrates via holes formed in the first planarization layer.

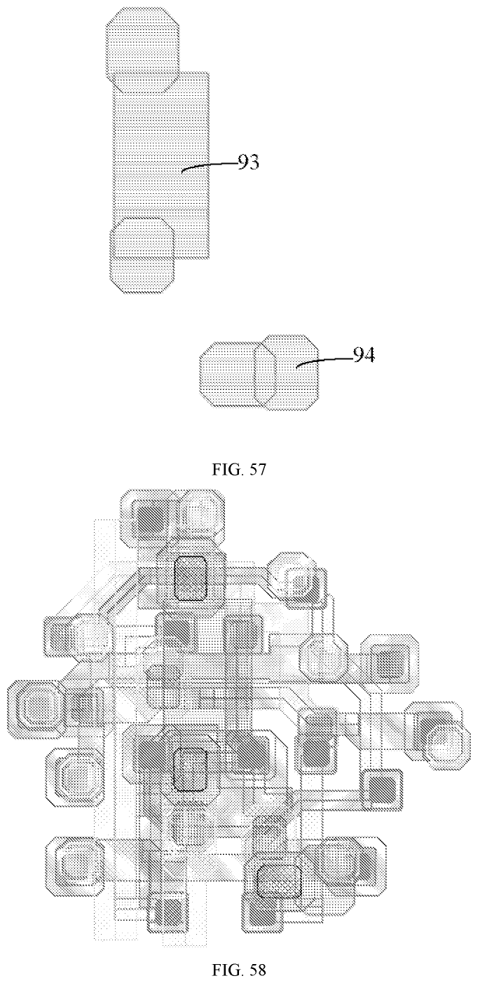

A second source and drain metal layer is deposited. FIG. 57 is a schematic view showing the structure of the second source and drain metal layer, the second source and drain metal layer includes a connection portion 93 and an anode transition structure 94. The connection portion 93 connects a first end of one transparent power supply portion VDD-T to a second end of another transparent power supply portion VDD-T adjacent to the one transparent power supply portion. The anode transition structure 94 is connected to the connection structure 85 and the anode pattern, respectively. FIG. 58 is a schematic view showing the structure after the second source and drain metal layer is provided thereon.

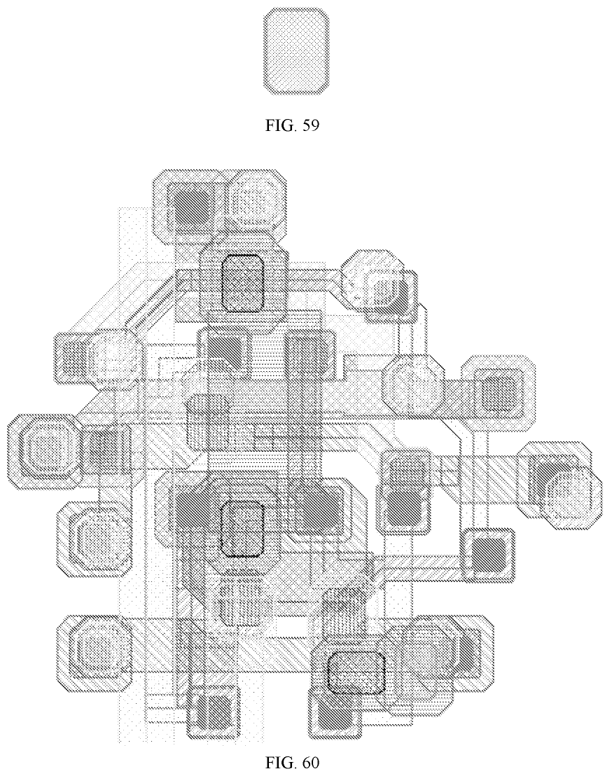

A second planarization layer is deposited. FIG. 59 is a diagram of a mask for the second planarization layer, and FIG. 60 is a schematic view showing the structure after the second planarization layer is provided thereon.

Embodiments of the present disclosure also provide a display device, including the display substrate provided in the above embodiments. The display device further includes a photosensitive sensor located at a non-displaying side of the display substrate and at least partially in the second display region.

It is to be noted that the display device may be any products or components with a display function, such as a television, a display, a digital photo frame, a mobile phone, a tablet computer. The display device further includes a flexible circuit board, a printed circuit board and a back panel.

With the display substrate provided in the embodiments, a pixel aperture can be formed by the pixel definition pattern BPDL over the anode pattern Ano, thereby ensuring normal displaying of sub-pixels. At the same time, the above-mentioned arrangement enables the pixel definition pattern BPDL to block at least a portion of a corresponding sub-pixel driving circuit, such that the reflectivity of the ambient light by the non-transparent metal film layer in the sub-pixel driving circuit can be reduced, thereby effectively improving the user experience. Meanwhile, by arranging the pixel definition pattern BPDL to include the black pixel definition pattern BPDL, so the pixel definition pattern BPDL can absorb the ambient light, thereby further reducing the reflection of the ambient light by the display substrate, and further improving the user experience.

The display device provided by the embodiments of the present disclosure also has the above-mentioned advantageous effects when including the display substrate provided by the above-mentioned embodiments, which will not be described in detail herein.

It is to be noted that the “same layer” in the embodiments of the present disclosure may refer to a film layer on the same structural layer. Alternatively, for example, the film layer in the same layer may be a layer structure formed by the following steps: forming a film layer by using the same film forming process for forming particular patterns; and then patterning the film layer by one patterning process using the same mask. Depending on the particular patterns, a single patterning process may include multiple processes including exposure, development, or etching, and the particular patterns in the resulting layer structure may or may not be continuous. The particular patterns may also be at different heights or have different thicknesses.

In the various method embodiments of the present disclosure, the serial number of the steps are not be used to define the order of the steps. For a person of ordinary skill in the art, any changes in the order of the steps without involving any inventive effort are also within the scope of the present disclosure.

It should be noted that the various embodiments described herein are described in a progressive manner with reference to the same or similar parts throughout the various embodiments, with each embodiment focusing on differences from the other embodiments. In particular, the method embodiments are described more simply because they are substantially similar to the product embodiments, with reference to the partial description of the product embodiments.

Unless defined otherwise, technical or scientific terms used in this disclosure shall have the ordinary meaning as understood by one of ordinary skill in the art to which this disclosure belongs. The terms “first”, “second”, and the like as use herein do not denote any order, quantity, or importance, but rather are used to distinguish one element from another. The terms “include” or “comprise”, and the like, means that the presence of an element or item preceding the word covers the presence of the element or item listed after the word and equivalents thereof, but does not exclude other elements or items. The terms “connect”, “couple” or “link” and the like are not limited to physical or mechanical connections, but may include electrical connections, whether direct or indirect. The terms “upper”, “lower”, “left”, “right” and the like are used only to indicate relative positional relationships that may change accordingly when the absolute position of the object being described changes.

It will be understood that when an element such as a layer, film, region or substrate is referred to as being “on” or “under” another element, it can be “directly on” or “directly under” the other element or intervening elements may be present.

In the description of the embodiments above, particular features, structures, materials, or characteristics may be combined in any suitable manner in any one or more embodiments or examples.

While the present disclosure has been described with reference to specific embodiments thereof, it will be understood by those skilled in the art that various changes may be made and equivalents may be substituted for elements thereof without departing from the scope of the disclosure. Accordingly, the protection scope of the present disclosure is set forth in the claims.

1. A display substrate, comprising: a base substrate and a plurality of sub-pixels arranged on the base substrate, wherein the sub-pixel comprises a sub-pixel driving circuit and a light-emitting element, the light-emitting element comprises an anode pattern, and the anode pattern is coupled to the sub-pixel driving circuit; wherein the display substrate further comprises:
a plurality of pixel definition patterns, wherein at least one pixel definition pattern in the plurality of pixel definition patterns comprises at least one pixel aperture, at least a portion of the light-emitting element is located in the pixel aperture, an orthographic projection of the at least one pixel definition pattern onto the base substrate covers at least a portion of an orthographic projection of the sub-pixel driving circuit onto the base substrate, and covers at least a portion of an orthographic projection of a gap between at least two adjacent sub-pixel driving circuits onto the base substrate, and the plurality of pixel definition patterns are configured to shield light.

2. The display substrate according to claim 1, wherein the plurality of pixel definition patterns are independent of one another.

3. The display substrate according to claim 1, wherein at least some pixel definition patterns in the plurality of pixel definition patterns are formed as a one-piece structure.

4. The display substrate according to claim 1, wherein the at least one pixel definition pattern comprises a black pixel definition pattern.

5. The display substrate according to claim 1, wherein the sub-pixel driving circuit comprises a first driving portion and/or a second driving portion, wherein an orthographic projection of the first driving portion onto the base substrate does not overlap with an orthographic projection of a corresponding one of the at least one pixel aperture onto the base substrate, and an orthographic projection of the second driving portion onto the base substrate overlaps with an orthographic projection of the corresponding one of the at least one pixel aperture onto the base substrate; and
the orthographic projection of the at least one pixel definition pattern onto the base substrate fully covers the orthographic projection of the first driving portion onto the base substrate.

6. The display substrate according to claim 5, wherein a minimum spacing between adjacent sub-pixel driving circuits in a first direction is greater than or equal to a width of one sub-pixel driving circuit in the first direction; a minimum spacing between adjacent sub-pixel driving circuits in a second direction is greater than or equal to one half of a width of one sub-pixel in the second direction; the first direction intersects with the second direction; and
the adjacent sub-pixel driving circuits in the first direction are electrically connected via a first signal line; and/or the adjacent sub-pixel driving circuits in the second direction are electrically connected via a second signal line;
or
wherein the plurality of sub-pixels are divided into a plurality of sub-pixel groups distributed in an array, each of the plurality of sub-pixel groups comprises at least two sub-pixels; the plurality of sub-pixel groups are distributed as islands; a minimum distance between two closest sub-pixel driving circuits in adjacent sub-pixel groups in a first direction is greater than or equal to a width of one sub-pixel driving circuit in the first direction; a minimum distance between two closest sub-pixel driving circuits in adjacent sub-pixel groups in a second direction is greater than or equal to one half of a width of one sub-pixel in the second direction; the first direction intersects with the second direction; and
the two closest sub-pixel driving circuits in the adjacent sub-pixel groups in the first direction are electrically connected via a first signal line; and/or the two closest sub-pixel driving circuits in the adjacent sub-pixel groups in the second direction are electrically connected via a second signal line.

7. (canceled)

8. The display substrate according to claim 6, wherein the first signal line is a transparent signal line and the first signal line comprises at least one of an initialization signal line, a gate line, a reset signal line or a light-emitting control signal line;
the second signal line is a transparent signal line and the second signal line comprises a data line and/or a power supply line.

9. The display substrate according to claim 3, wherein in the at least some pixel definition patterns formed as the one-piece structure, a spacing region is arranged between adjacent pixel definition patterns, an orthographic projection of a boundary of the spacing region onto the base substrate surrounds at least a portion of the first signal line and/or at least a portion of the second signal line in the display substrate.

10. The display substrate according to claim 1, wherein an orthographic projection of an outer boundary of the pixel definition pattern onto the base substrate is rectangular.

11. The display substrate according to claim 1, wherein an orthographic projection of an outer boundary of the pixel definition pattern onto the base substrate is circular.

12. The display substrate according to claim 6, wherein the pixel definition pattern comprises a pixel definition main body portion and at least one pixel definition protruding portion, the at least one pixel definition protruding portion is coupled to the pixel definition main body portion, an overlapping area between an orthographic projection of the pixel definition main body portion onto the base substrate and an orthographic projection of a corresponding sub-pixel driving circuit onto the base substrate, is greater than an overlapping area between an orthographic projection of the at least one pixel definition protruding portion onto the base substrate and the orthographic projection of the corresponding sub-pixel driving circuit onto the base substrate.

13. The display substrate according to claim 6, wherein sub-pixel driving circuits comprised in one of the plurality of sub-pixel groups are arranged along the first direction; and
pixel definition patterns corresponding to sub-pixel driving circuits in a same sub-pixel group are formed as a one-piece structure, and the pixel definition patterns formed as the one-piece structure cover at least a portion of a region located between adjacent sub-pixel driving circuits.

14. The display substrate according to claim 13, wherein in sub-pixel groups located in a same column in the second direction, pixel definition patterns corresponding to sub-pixel driving circuits are formed as a one-piece structure.

15. The display substrate according to claim 1, wherein the display substrate further comprises an encapsulation layer and a plurality of black matrix patterns, the encapsulation layer is located between the plurality of black matrix patterns and the base substrate, an orthographic projection of one of the plurality of black matrix patterns onto the base substrate at least partially overlaps with an orthographic projection of a corresponding one of the plurality of pixel definition patterns onto the base substrate.

16. The display substrate according to claim 15, wherein a contour of the orthographic projection of the one of the plurality of black matrix patterns onto the base substrate is substantially the same as a contour of the orthographic projection of the corresponding one of the plurality of pixel definition patterns onto the base substrate.

17. The display substrate according to claim 15, wherein an orthographic projection of an inner boundary of the one of the plurality of black matrix patterns onto the base substrate surrounds an orthographic projection of an inner boundary of the corresponding one of the plurality of pixel definition patterns onto the base substrate.

18. The display substrate according to claim 15, wherein an orthographic projection of an outer boundary of one of the plurality of pixel definition patterns onto the base substrate surrounds an orthographic projection of a corresponding one of the plurality of black matrix patterns onto the base substrate.

19. The display substrate according to claim 1, wherein the display substrate comprises a first display region and a second display region, the first display region is located at least at one side of the second display region; and
the plurality of sub-pixels comprises a plurality of first sub-pixels and a plurality of second sub-pixels, the plurality of first sub-pixels are located in the first display region, the plurality of second sub-pixels are located in the second display region, a pixel density for the plurality of second sub-pixels is less than or equal to a pixel density for the plurality of first sub-pixels, the plurality of pixel definition patterns are located in the second display region.

20. The display substrate according to claim 19, wherein a light transmittance of the first display region is less than a light transmittance of the second display region.

21. A display device, comprising a display substrate, wherein the display substrate comprises a base substrate and a plurality of sub-pixels arranged on the base substrate, wherein the sub-pixel comprises a sub-pixel driving circuit and a light-emitting element, the light-emitting element comprises an anode pattern, and the anode pattern is coupled to the sub-pixel driving circuit;
wherein the display substrate further comprises a plurality of pixel definition patterns, wherein at least one pixel definition pattern in the plurality of pixel definition patterns comprises at least one pixel aperture, at least a portion of the light-emitting element is located in the pixel aperture, an orthographic projection of the at least one pixel definition pattern onto the base substrate covers at least a portion of an orthographic projection of the sub-pixel driving circuit onto the base substrate, and covers at least a portion of an orthographic projection of a gap between at least two adjacent sub-pixel driving circuits onto the base substrate, and the plurality of pixel definition patterns are configured to shield light;
wherein the display device further comprises a photosensitive sensor, the photosensitive sensor is located at a non-displaying side of the display substrate and at least a portion of the photosensitive sensor is located in the second display region.
